(19) United States
(12) Patent Application Publication
(10) Pub. No.: US 2011/0049617 A1
(43) Pub. Date: Mar. 3, 2011

(54) SEMICONDUCTOR DEVICE

(76) Inventors: Sungun Kwon, Jeonju-si (KR); Jaeseung Hwang, Suwon-si (KR)

(21) Appl. No.: 12/868,048

(22) Filed: Aug. 25, 2010

(30) Foreign Application Priority Data
Sep. 3, 2009 (KR) 10-2009-0083132

(51) Int. Cl. H01L 29/78

(52) U.S. Cl. 257/329; 257/E29.262

(57) ABSTRACT

A semiconductor device is provided. The semiconductor device includes a substrate and a plurality of material layers. The substrate includes a concave portion having a bottom surface and a side surface, and a protruded portion extended from the side surface. The plurality of material layers have flat portions on the bottom surface and side portions extended over the side surface from the flat portions, and spaced from each other. Here, at least one of the sidewall portions of the material layers has a thickness greater than a thickness of the flat portions of the material layers.

### CROSS-REFERENCE TO RELATED APPLICATIONS

This U.S. non-provisional patent application claims priority under 35 U.S.C. §119 to Korean Patent Application No. 10-2009-0083132, filed on Sep. 3, 2009, the contents of which are incorporated by reference herein in its entirety.

### BACKGROUND

The present disclosure relates to a semiconductor device, and more particularly to a semiconductor device having three-dimensional structure.

With the rapid development of semiconductor technologies, higher integration, lower power consumption and higher speed operation are continual design goals.

As semiconductor devices become more highly integrated, it becomes more difficult to secure a margin in contact processes integrating semiconductor devices with conductive lines and complex patterns. When a defect occurs during the contact process, the reliability of the semiconductor device is reduced, resulting in degradation of the performance of electronic devices including the semiconductor device.

Accordingly, a need exists to increase the reliability of highly-integrated semiconductor devices by securing a margin of the contact process having complex patterns.

### SUMMARY

The present disclosure provides a semiconductor device having improved reliability and a method for forming a semiconductor device without an opening having a high step difference.

Embodiments of the inventive concept provide semiconductor devices including: a substrate including a concave portion having a bottom surface and a side surface, and a protruded portion extended from the side surface; and a plurality of material layers having flat portions on the bottom surface and side portions extended over the side surface from the flat portions, and spaced from each other, wherein at least one of the sidewall portions of the material layers has a thickness greater than a thickness of the flat portions of the material layers.

According to an embodiment, the semiconductor devices may further include gate patterns having gate pattern flat portions between the flat portions of the material layers and gate pattern sidewall portions between the sidewall portions of the material layers. Here, the material layers may include a material having insulating properties.

According to an embodiment, the semiconductor devices may further include conductive patterns provided on upper surfaces of the gate pattern sidewall portions. Here, the conductive patterns may have a width greater than a width of the gate pattern sidewall portions.

According to an embodiment, the semiconductor devices may further include gate insulating patterns between the material layers. Here, the material layers may include a material having conductive properties.

According to an embodiment, the semiconductor devices may further include conductive patterns provided on upper surfaces of the sidewall portions of the material layers. Here, the conductive patterns may have a width smaller than a width of the sidewall portions of the material layers.

According to an embodiment, the sidewall portions of the material layers may have main sidewall portions provided by the same process as a process providing the flat portions, and auxiliary sidewall portions contacting the main sidewall portions.

According to an embodiment, the sidewall portions of the material layers may have a width greater than an interval between two adjacent material layers of the material layers.

According to an embodiment, upper surfaces of the sidewall portions of the material layers are coplanar with an upper surface of the protruded portion, and the upper surface of the protruded portion may be parallel to the bottom surface of the concave portion of the substrate.

According to an embodiment, the semiconductor devices may further include an active pillar upwardly extended from the bottom surface of the concave portion of the substrate and facing side surfaces of the flat portions of the material layers.

According to an embodiment, the semiconductor devices may further include an active pillar extended from the bottom surface of the concave portion of the substrate and passing through the flat portions of the material layers.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a plan view illustrating a semiconductor device according to an embodiment;

FIG. 2 is a cross-sectional view illustrating a semiconductor device according to an embodiment;

FIGS. 3A through 3G are cross-sectional views illustrating a method for forming a semiconductor device according to an embodiment;

FIGS. 4A through 4C are cross-sectional views illustrating a method for forming a semiconductor device according to an embodiment;

FIG. 5 is a cross-sectional view illustrating a semiconductor device according to an embodiment;

FIGS. 6A through 6F are cross-sectional views illustrating a method for forming a semiconductor device according to an embodiment;

FIGS. 7A through 7C are cross-sectional views illustrating a method for forming a semiconductor device according to an embodiment;

FIG. 8 is a plan view illustrating a semiconductor device according to an embodiment;

FIG. 9 is a cross-sectional view illustrating a semiconductor device according to an embodiment;

FIGS. 10A through 10E are cross-sectional views illustrating a method for forming a semiconductor device according to an embodiment;

FIGS. 11A through 11C are cross-sectional views illustrating a method for forming a semiconductor device according to an embodiment;

FIG. 12 is a cross-sectional view illustrating a semiconductor device according to an embodiment;

FIGS. 13A through 13C are cross-sectional views illustrating a method for forming a semiconductor device according to an embodiment; and

FIGS. 14A through 14C are cross-sectional views illustrating a method for forming a semiconductor device according to an embodiment.

FIG. 15 is a block diagram illustrating an exemplary memory card 1100 including semiconductor devices according to an embodiment.

FIG. 16 is a block diagram illustrating a data processing system including a memory system having semiconductor devices according to an embodiment.

### DETAILED DESCRIPTION OF THE EMBODIMENTS

Exemplary embodiments of the inventive concept will be described below in more detail with reference to the accompanying drawings. Like reference numerals may refer to like elements throughout the drawings and the specification.

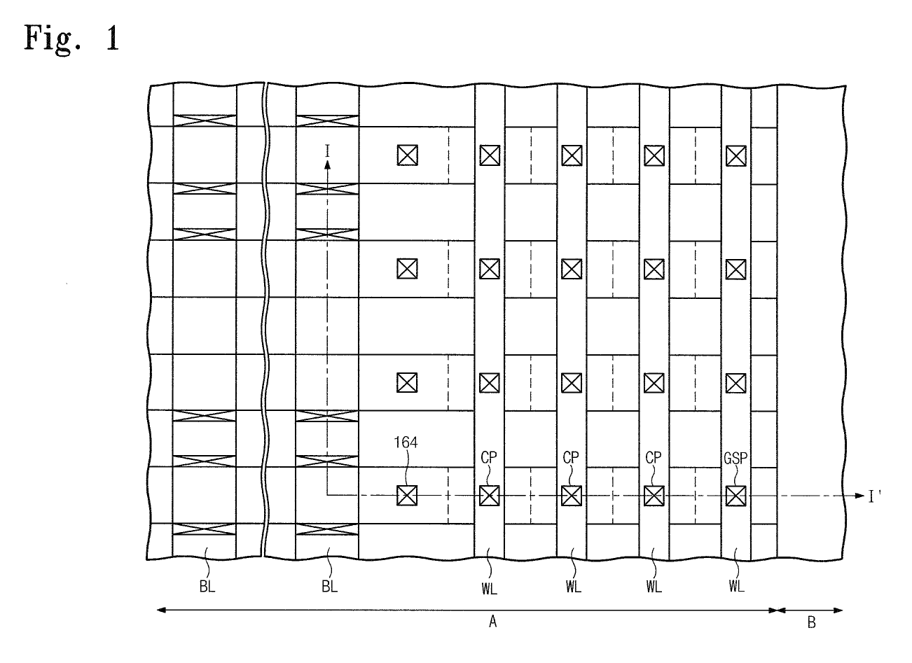

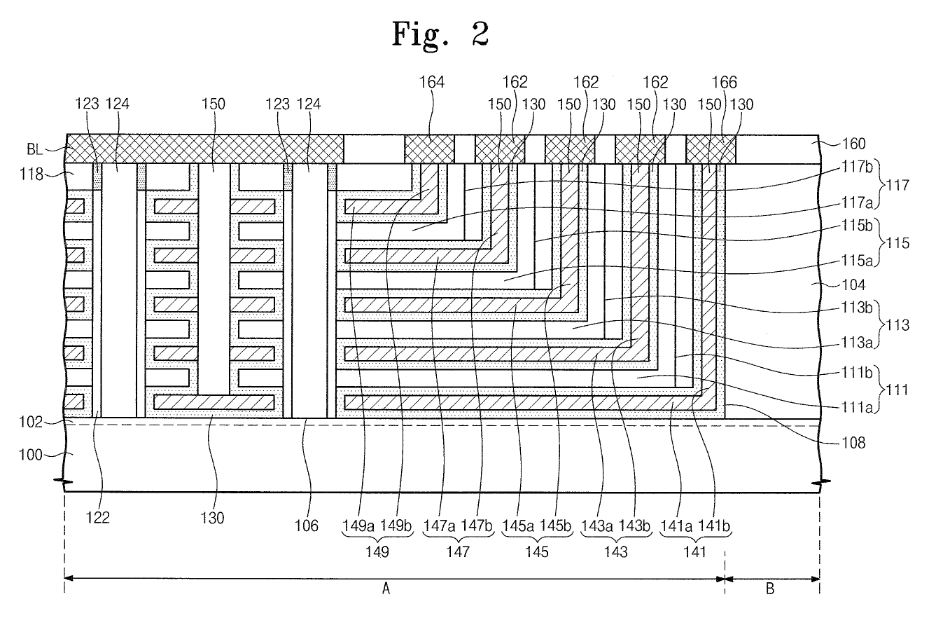

FIG. 1 is a plan view illustrating a semiconductor device according to an embodiment, and FIG. 2 is a cross-sectional view taken along line I-I′ of FIG. 1.

Referring to FIGS. 1 and 2, a substrate 100 may be provided. The substrate 100 may be a semiconductor-based semiconductor substrate. The substrate 100 may include a well region. The well region may include a first conductive type dopant. The substrate 100 may include a concave portion A having a bottom surface 106 and a side surface 108. The substrate 100 may include a protruded portion B extended from the side surface 108 of the concave portion A. An insulating layer 104 may be disposed on the protruded portion B to define the protruded portion B. In contrast, the concave portion A of the substrate 100 may be defined by recessing the concave portion A of the substrate 100. In this case, the substrate 100 including the concave portion A and the protruded portion B may be a one body.

An active pillar 122 may be disposed to be upwardly extended from the bottom surface 106 of the concave portion A of the substrate 100. The active pillar 122 may be extended perpendicular to the substrate 100. The active pillar 122 may be connected to a common source region 102 at one end thereof. The active pillar 122 may be connected to a bit line BL at the other end thereof. The active pillar 122 may include a single or polycrystal semiconductor.

The common source region 102 may be disposed in the substrate 100 to be electrically connected to the active pillar 122. The common source region 102 may be disposed to have a plate form in a cell region of the substrate 100. The common source region 102 may include a high-concentration of dopant. The dopant included in the common source region 102 may be a second conductive type dopant different from the dopant included in the well. For example, when the well includes a p-type dopant, the common source region 102 may include an n-type dopant.

Material layers may be disposed on the substrate 100 to be spaced from each other. The material layers may include materials having insulating properties. The material layers may include inter-cell gate insulating layers 113 and 115, a first intergate insulating layer 111 and a second intergate insulating layer 117. The insulating layers 111, 113, 115, and 117 may include insulating layer flat portions 111a, 113a, 115a, and 117a, respectively, on the bottom surface 106 of the concave portion A, and insulating layer sidewall portions 111b, 113b, 115b, and 117b, respectively. The insulating layer sidewall portions 111b, 113b, 115b, and 117b are extended over the side surface 108 of the concave portion A from the insulating layer flat portions 111a, 113a, 115a, and 117a, respectively. At least one of the insulating layer sidewall portions 111b, 113b, 115b, and 117b may have a thickness greater than a thickness of a corresponding insulating layer flat portion of the insulating layer flat portions 111a, 113a, 115a, and 117a. The insulating layer sidewall portions 111b, 113b, 115b, and 117b may have a width greater than an interval between two adjacent insulating layers of the insulating layers 111, 113, 115, and 117. For example, a width of the insulating layer sidewall portion 111b, 113b, 115b, and 117b may be greater than an interval between the insulating layers 111 and 113; between the insulating layers 113 and 115 or between the insulating layers 113 and 111; between the insulating layers 115 and 117 or between the insulating layers 115 and 113; and between the insulating layers 117 and 115, respectively. A string select insulating layer 118 may be disposed spaced from the second intergate insulating layer 117 on the substrate 100.

Gate pattern flat portions 141a, 143a, 145a, 147a, and 149a may be disposed between the first intergate insulating flat portion 111a and the bottom surface 106 of the substrate 100, between the insulating layer flat portions 111a, 113a, 115a and 117a, and between the second intergate insulating layer flat portion 117a and the string select insulating layer 118.

Gate pattern sidewall portions 141b, 143b, 145b, 147b, and 149b may be disposed between the first intergate insulating layer sidewall portion 111b and the side surface 108 of the substrate 100, between the insulating layer sidewall portions 111b, 113b, 115b, and 117b, and between the second intergate insulating layer sidewall portion 117b and the string select insulating layer 118.

Gate patterns 141, 143, 145, 147, and 149 may include the gate pattern flat portions 141a, 143a, 145a, 147a, and 149a and the gate pattern sidewall portions 141b, 143b, 145b, 147b, and 149b, respectively. The gate patterns 141, 143, 145, 147, and 149 may include cell gate patterns 143, 145, 147, a ground select gate pattern 141, and a string select gate pattern 149. The gate patterns 141, 143, 145, 147, and 149 may be spaced from each other by the insulating layers 111, 113, 115, and 117.

The upper surfaces of the gate pattern sidewall portions 141b, 143b, 145b, 147b and 149b may be coplanar with the upper surface of the insulating layer 104 of the protruded portion B. The lower surface of the insulating layer 104 of the protruded portion B may be coplanar with the bottom surface 106 of the concave portion A.

The gate patterns 141, 143, 145, 147, and 149 may be stacked over the substrate 100 along the sidewall of the active pillar 122. The gate patterns 141, 143, 145, 147, and 149 may have a linear shape extending in a first direction over the substrate 100. The gate patterns 141, 143, 145, 147, and 149 stacked along the sidewall of the active pillar 122 may form one vertical type cell string. The active pillar 122 may face the sidewalls of the gate pattern flat portions 141a, 143a, 145a, 147a, and 149a. Although three cell gate patterns 143, 145 and 147 are shown in the drawing for convenience of explanation, the number of the cell gate patterns is not limited thereto.

An information storage layer 130 may be disposed between the cell gate patterns 143, 145 and 147 and the sidewall of the active pillar 122. The information storage layer 130 may be disposed between the gate patterns 141, 143, 145, 147, and 149 and the insulating layers 111, 113, 115, 117, and 118. The information storage layer 130 may include a tunnel dielectric layer, a trap insulating layer, and a blocking layer, which are sequentially stacked on the sidewall of the active pillar 122.

The tunnel dielectric layer may be a single layer or a multilayer structure. For example, the tunnel dielectric layer may include at least one of silicon oxynitride, silicon nitride, silicon oxide, and metal oxide.

The trap insulating layer may include charge trap sites capable of storing electric charges. For example, the trap insulating layer may include at least one of silicon nitride, metal nitride, metal oxynitride, metal silicon oxide, metal silicon oxynitride, and nano dots.

The blocking layer may include at least one selected from a silicon oxide layer, a silicon nitride layer, a silicon oxynitride layer, and a high dielectric layer. The high dielectric layer may include at least one selected from a metal oxide layer, a metal nitride layer, and a metal oxynitride layer. The high electric layer may include Hafnium (Hf), Zirconium (Zr), Aluminum (Al), Tantalum (Ta), Lanthanum (La), Cerium (Ce), and Praseodymium (Pr). The dielectric constant of the blocking layer may be greater than the dielectric constant of the tunnel insulating layer.

The cell gate patterns 143, 145, and 147 may form word lines, respectively. First conductive patterns 162 may be provided to the upper surfaces of the cell gate pattern sidewall portions 143b, 145b, and 147b. The first conductive patterns 162 may have a width greater than the width of the cell gate pattern sidewall portions 143b, 145b and 147b. The first conductive patterns 162 may be cell plugs CP. The word lines may be connected to wide word lines WL through the cell plugs CP, respectively. In contrast, the first conductive patterns 162 may be the wide word lines WL.

The ground select gate pattern 141 may be disposed between the substrate 100 and the cell gate pattern 143. The ground select gate pattern 141 may control electrical connection to the active pillar 122 and the substrate 100. A second conductive pattern 166 may be provided on the upper surface of the sidewall portion 141b of the ground select gate pattern 141. The second conductive pattern 166 may have a width greater than a width of the sidewall portion 141b of the ground select gate pattern 141. The second conductive pattern 166 may be a ground select plug GSP. The ground select gate pattern 141 may be connected to a ground select line GSL through the ground select plug GSP. In contrast, the second conductive pattern 166 may be a ground select line GSL.

The string select gate pattern 149 may be disposed over the cell gate pattern 147 disposed at the highest position of the cell gate patterns 143, 145, and 147. The string select gate pattern 149 may be extended in the first direction parallel to the substrate 100. A third conductive pattern 164 may be provided on the upper surface of the sidewall portion 149b of the string select gate pattern 149. The third conductive pattern 164 may have a width greater than a width of the sidewall portion 149b of the string gate pattern 149. The third conductive pattern 164 may be a plug for connection with the string select line. The string select line may be extended in the first direction. In contrast, the third conductive pattern 164 may be the string select line.

Since the gate pattern sidewall portions 141b, 143b, 145b, 147b, and 149b have a width greater than a width of the gate pattern flat portions 141a, 143a, 145a, 147a, and 149a, a margin can be secured by a process of forming the conductive patterns. Also, since the widths of the gate pattern flat portions 141a, 143a, 145a, 147a, and 149a are not increased, a margin can be secured in the process of forming the conductive patterns, and a highly integrated semiconductor device can also be provided.

A bit line BL may be disposed on the string select gate pattern 149. The bit line BL may be disposed to cross the string select gate pattern 149. The bit line BL may be extended in a second direction crossing the first direction in which the string select gate pattern 149 is extended. The first and second directions may be perpendicular to each other. The string select insulating layer 118 may be disposed between the string select gate pattern 149 and the bit line BL.

The bit line BL may be connected to the active pillar 122 via a drain region 123 located on the upper portion of the active pillar 122. The drain region 123 may include a high-concentration of dopant region on the upper portion of the active pillar 122. According to an embodiment, the bit line BL may be connected to the drain region 123 via a certain plug. A plurality of active pillars 122 may be disposed on the substrate 100. The electrical connection between the bit line BL and the active pillar 122 may be controlled by the string select gate pattern 149.

The plurality of active pillars 122 extended in the second direction may be connected to the same bit line BL. The active pillars 122 adjacent to each other may be insulated by the insulating materials 124.

Hereinafter, a method for forming a semiconductor device according to an embodiment will be described in detail.

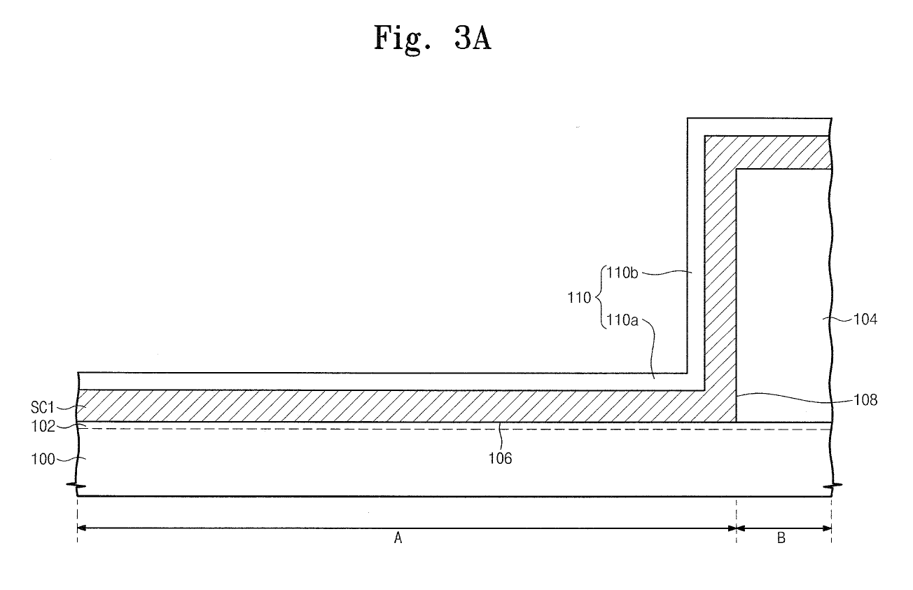

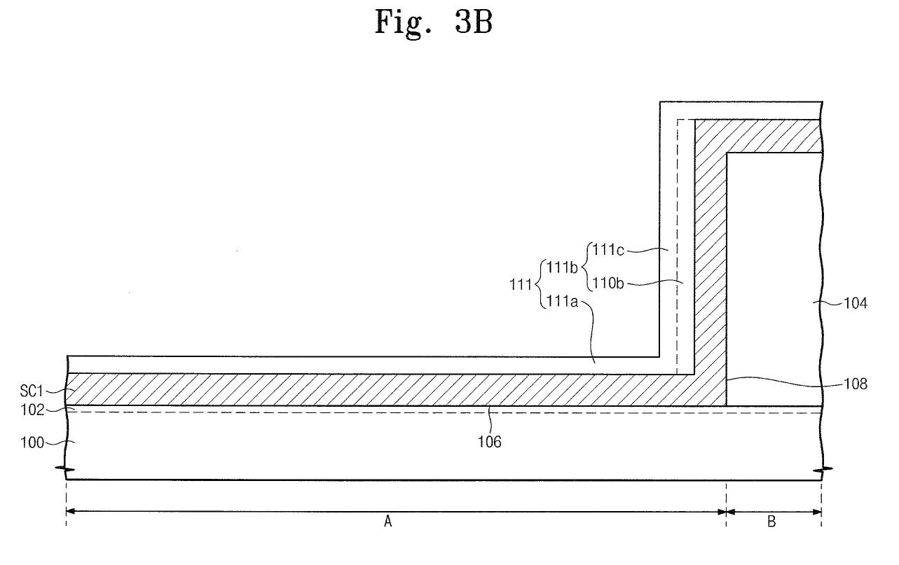

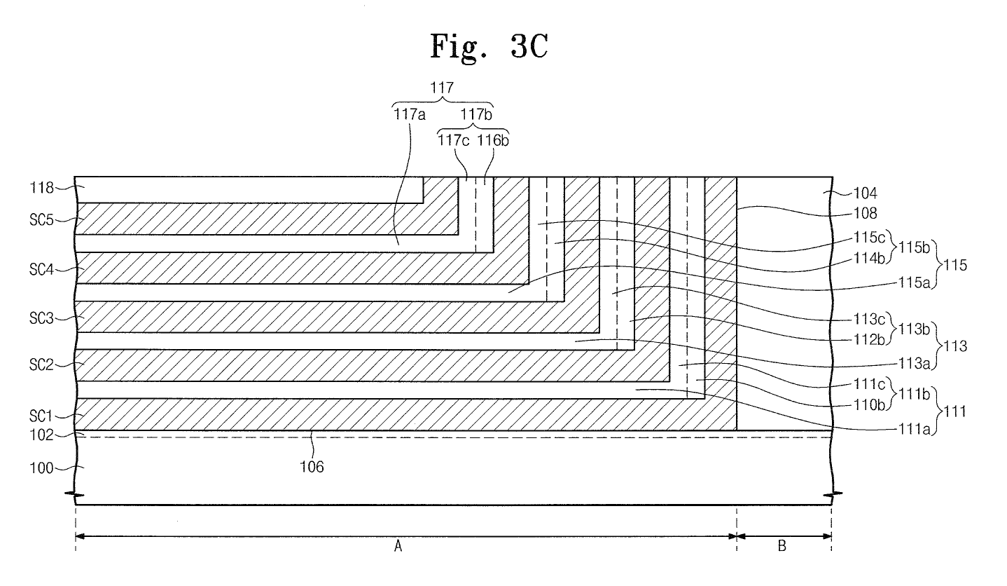

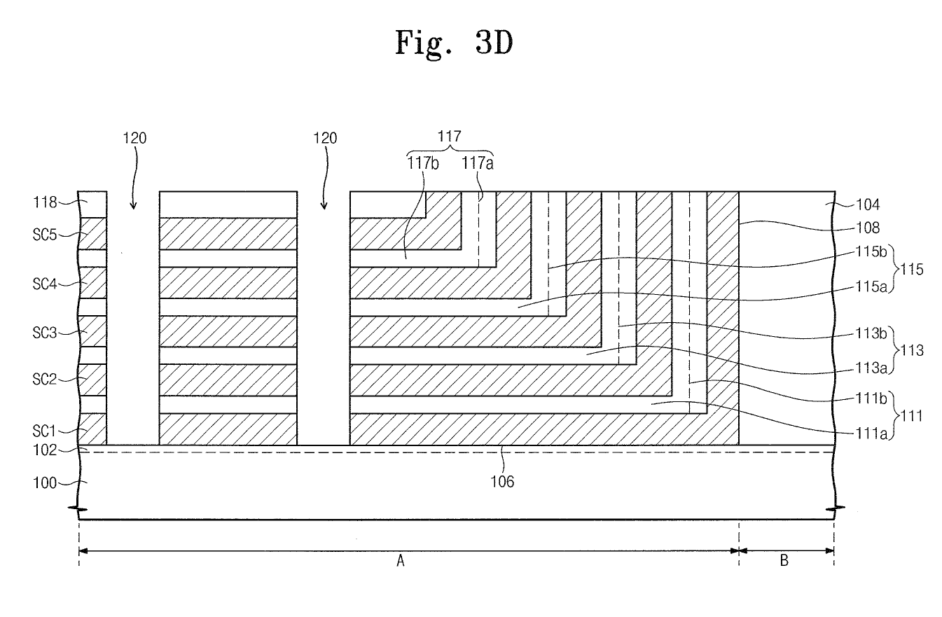

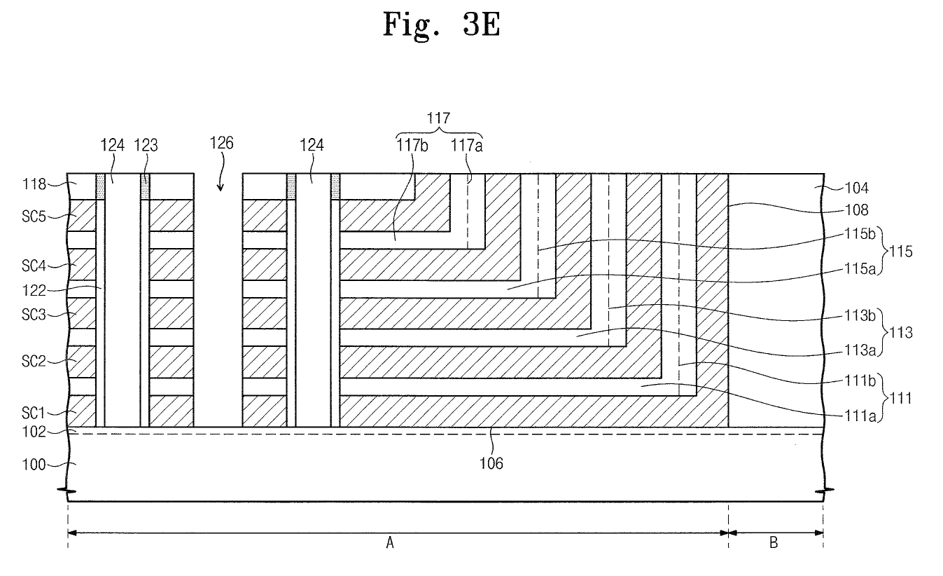

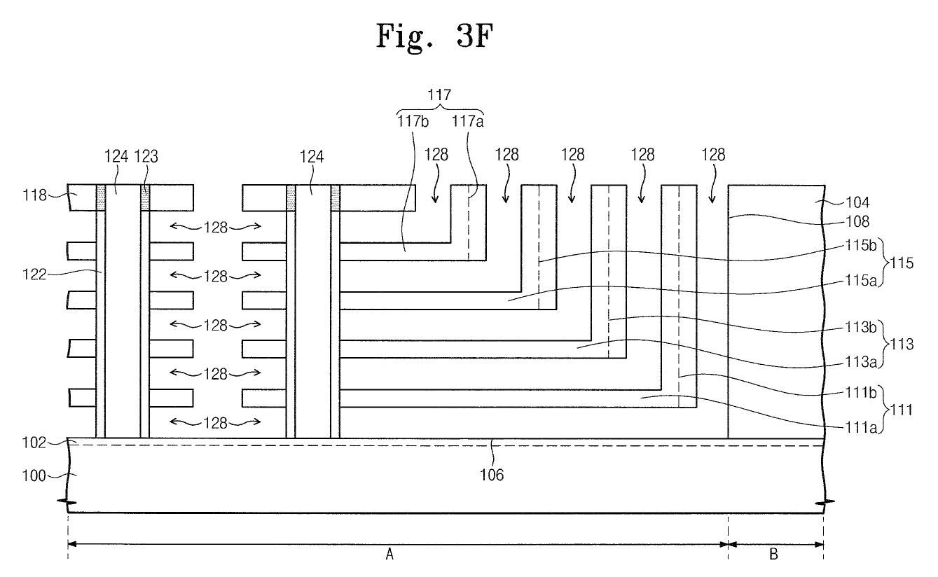

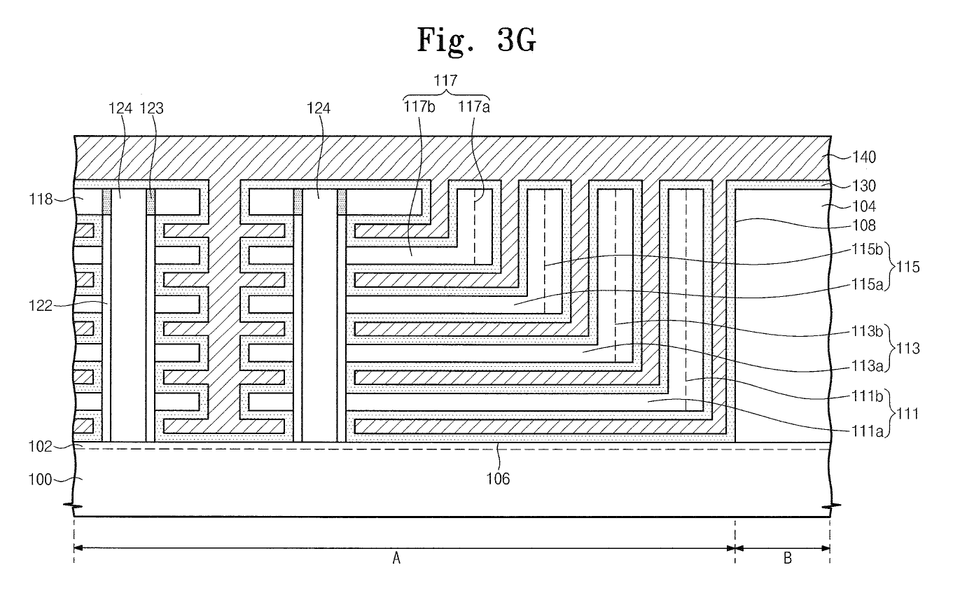

FIGS. 3A through 3G are cross-sectional views illustrating a method for forming a semiconductor device according to an embodiment.

Referring to FIG. 3A, a substrate 100 may be provided. The substrate 100 may include a concave portion A having a bottom surface 106 and a side surface 108, and a protruded portion B extended from the side surface 108. An insulating layer 104 may be formed on the substrate 100 to define the concave portion A and the protruded portion B. The insulating layer 104 may include a silicon oxide. In contrast, the substrate 100 may be etched to define the concave portion A and the protruded portion B.

The substrate 100 may be a semiconductor (e.g., p-type silicon wafer) with a single crystal structure. The substrate 100 may include a well. The well may be formed by implanting a dopant into the substrate 200. The dopant may be implanted into the substrate 100 through a doping process including an ion implantation process or a plasma implantation process. A common source region 102 may be provided on the upper surface of the substrate 100. The common source region 102 may be formed by doping the well with a dopant. The common source region 102 may include a dopant of a conductive type different from the well. For example, the well may include a p-type dopant, and the common source region 102 may include an n-type dopant.

A first sacrificial layer SC1 may be formed on the substrate 100. The first sacrificial layer SC1 may be formed on the bottom surface 106 and the side surface 108 of the concave portion A of the substrate 100. The first sacrificial layer SC1 may be extended over the protruded portion B. A first auxiliary intergate insulating layer 110 may be formed on the first sacrificial layer SC1. The first auxiliary intergate insulating layer 110 may include a first auxiliary intergate insulating layer flat portion 110a formed on the bottom surface 106 of the concave portion A, and a first auxiliary intergate insulating layer sidewall portion 110b extended over the side surface 108 from the first auxiliary intergate insulating layer flat portion 110a. The first auxiliary intergate insulating layer 110 may be extended over the protruded portion B.

Referring to FIG. 3B, an etching process may be performed on the first auxiliary intergate insulating layer 110 using the first sacrificial layer SC1 as an etch stop layer. The etching process may be an anisotropic etching process. Due to the etching process, the first auxiliary intergate insulating layer flat portion 110a of the first auxiliary intergate insulating layer 110 formed over the concave portion A may be removed. The first auxiliary intergate insulating layer sidewall portion 110b may remain.

After the etching process, a first intergate insulating layer 111 may be formed over the substrate 100. The first intergate insulating layer 111 may include a first intergate insulating layer flat portion 111a over the bottom surface 106 of the concave portion A of the substrate 100. The first intergate insulating layer 111 may include a first intergate insulating layer sidewall portion 111b extended over the side surface 108 of the concave portion A from the first intergate insulating layer flat portion 111a. The first intergate insulating layer sidewall portion 111b may include a main first intergate insulating layer sidewall portion 111c provided in the same process as performed on the first intergate insulating layer flat portion 111a, and the first auxiliary intergate insulating layer sidewall portion 110b contacting the main first intergate insulating layer sidewall portion 111c.

Referring to FIG. 3C, as described in connection with FIG. 3B, sacrificial layers SC2 to SC5 and insulating layers 113, 115, and 117 may be alternately formed over the first intergate insulating layer 111. The insulating layers 111, 113, 115 and 117 may include insulating layer flat portions 111a, 113a, 115a and 117a, respectively, over the bottom surface 106 of the concave portion A of the substrate 100. The insulating layers 111, 113, 115, and 117 may include insulating layer sidewall portions 111b, 113b, 115b, and 117b, respectively. The insulating layer sidewall portions 111b, 113b, 115b, and 117b are extended over the sidewall 108 of the concave portion A from the insulating layer flat portions 111a, 113a, 115a, and 117a, respectively. The insulating layer sidewall portions 111b, 113b, 115b, and 117b may include main insulating layer sidewall portions 111c, 113c, 115c, and 117c, respectively, which are provided in the same process as performed on the insulating layer flat portions 111a, 113a, 115a, and 117a, respectively, and auxiliary insulating layer sidewall portions 110b, 112b, 114b, and 116b, respectively, contacting the main insulating layer sidewall portions 111c, 113c, 115c, and 117c, respectively. The insulating layer sidewall portions 111b, 113b, 115b, and 117b may have a thickness greater than a thickness of the insulating layer flat portions 111a, 113a, 115a, and 117a, respectively. A string select insulating layer 118 may be formed on the fifth sacrificial layer SC5.

The insulating layers 111, 113, 115, and 117 may include a silicon oxide. The sacrificial layers SC1 to SC5 may be formed of materials that can be selectively etched such that the insulating layers 111, 113, 115, and 117 are minimally etched. For example, the sacrificial layers SC1 to SC5 may include a silicon nitride.

A planarization process may be performed using the upper surface of the protruded portion A as an etch stop layer. The planarization process may be performed by an etchback process or a Chemical Mechanical Polishing (CMP) process. Thus, the upper surface of the protruded portion A may be coplanar with the upper surface of the insulating layer sidewall portions 111b, 113b, 115b, and 117b.

Referring to FIG. 3D, the insulating layers 111, 113, 115, and 117, the string select insulating layer 118, and the sacrificial layers SC1 to SC5 are patterned to form a first opening 120 exposing the bottom surface 106 of the concave portions A of the substrate 100. The first opening 120 may be formed by an anisotropic etching process.

Referring to FIG. 3E, an active pillar 122 may be formed to cover the inner wall of the first opening 120. The active pillar 122 may be formed to conformally cover the inner wall of the first opening 120 using one of Chemical Vapor Deposition (CVD) or Atomic Layer Chemical Vapor Deposition (ALCVD). The active pillar 122 may be formed to have the same conductive type as the substrate 100, and thus may be electrically connected to the substrate 100. For example, the active pillar 122 may include silicon with a single crystal structure connected to the substrate 100 without a crystal flaw. For this, the active pillar 122 may be grown from the exposed substrate 100 using one of epitaxial techniques. The residual space of the first opening 120 may be filled with insulating materials (e.g., silicon oxide, silicon nitride, or air) 124. A drain region 123 may be formed on the active pillar 122.

The insulating layers 111, 113, 115, and 117, the string select insulating layer 118, and the sacrificial layer SC1 to SC5 may be patterned to form a preliminary gate isolation region 126 exposing the bottom surface 106 of the concave portion A of the substrate 100. For example, the preliminary gate isolation region 126 may be formed between adjacent active pillars 122. Thus, the sidewalls of the insulating layers 111, 113, 115, and 117 and the sacrificial layers SC1 to SC5 may be exposed by the preliminary gate isolation region 126. A process for forming the preliminary gate isolation region 126 may be similar to the process for forming the first opening 120.

Referring to FIG. 3F, the sacrificial layers SC1 to SC5 exposed by the preliminary isolation region 126 may be removed. Thus, gate regions 128 may be formed between the insulating layers 111, 113, 115, and 117 and the string select insulating layer 118 to expose the sidewall of the active pillar 122. The removal of the sacrificial layers SC1 to SC5 may be achieved using an etch recipe of having etch selectivity with respect to the insulating layers 111, 113, 115, and 117, the string select insulating layer 118, the substrate 100, the active pillar 122, and the insulating material 124. The removal of the sacrificial layers SC1 to SC5 may be performed by a dry or wet method, and an isotropic etching method.

Referring to FIG. 3G, an information storage layer 130 may be conformally formed over the structure in which the gate regions 128 have been formed. The information storage layer 130 may include a tunnel dielectric layer, a trap insulating layer, and a blocking insulating layer, which are sequentially stacked on the sidewall of the active pillar 122.

A preliminary gate conductive layer 140 may be formed on the information storage layer 130 to fill the preliminary gate isolation region 126 and the gate region 128. The preliminary gate conductive layer 140 may include at least one of a polycrystal silicon layer, silicide layers and metal layers that are formed by a CVD or ALD method. Since the information storage pattern 130 may be formed on the substrate 100, the preliminary gate conductive layer 140 may be electrically separated from the substrate 100.

Referring again to FIG. 2, portions of the information storage layer 130 and the preliminary gate conductive layer 140 may be removed using an upper surface of the string select insulating layer 118 as an etch stop layer. The preliminary gate conductive layer 140 formed on the preliminary gate isolation region 126 may be removed, and then a gapfill insulating layer 150 may be formed on the preliminary gate isolation region 126. The preliminary gate conductive layer 140 may be patterned to form gate patterns 141, 143, 145, 147, and 149. The gate patterns 141, 143, 145, 147, and 149 may include a string select gate pattern 149, cell gate patterns 143, 145 and 147, and a ground select gate pattern 141.

Removing the preliminary conductive layer 140 formed on the preliminary gate isolation region 126 may include performing etching through a patterning process until the upper surface of the ground select gate pattern 141 except for the substrate 100 is exposed. Pillars that are two-dimensionally arrayed may be formed by patterning the active pillar 122.

An interlayer dielectric layer 160 may be formed on the substrate 100. Second openings passing through the interlayer dielectric layer 160 and exposing the gate pattern sidewall portions 141b, 143b, 145b, 147b, and 149b may be formed. Conductive patterns 162 and 166 may be formed to fill the second openings. The conductive patterns 162, 164, and 166 may have a width greater than a width of the gate pattern sidewall portions 141a, 143a, 145a, and 149a.

Hereinafter, a method for forming a semiconductor device according to an embodiment will be described in detail.

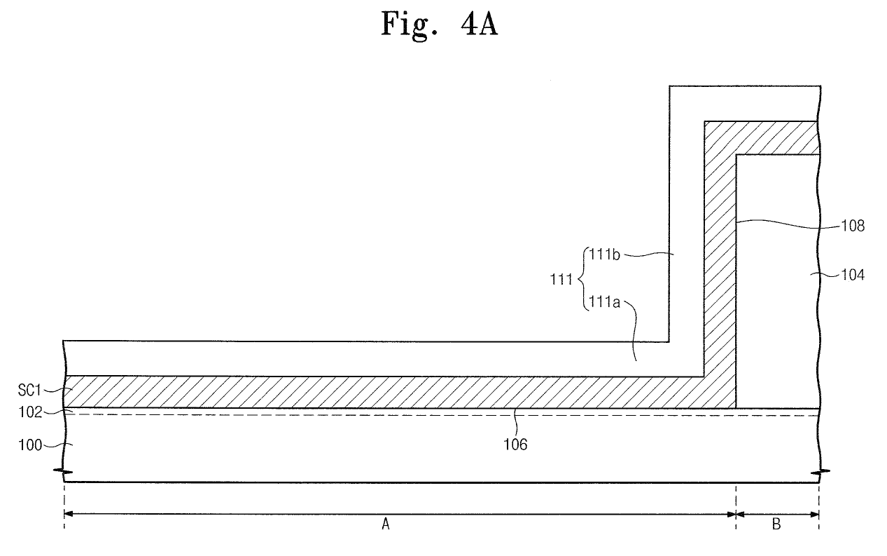

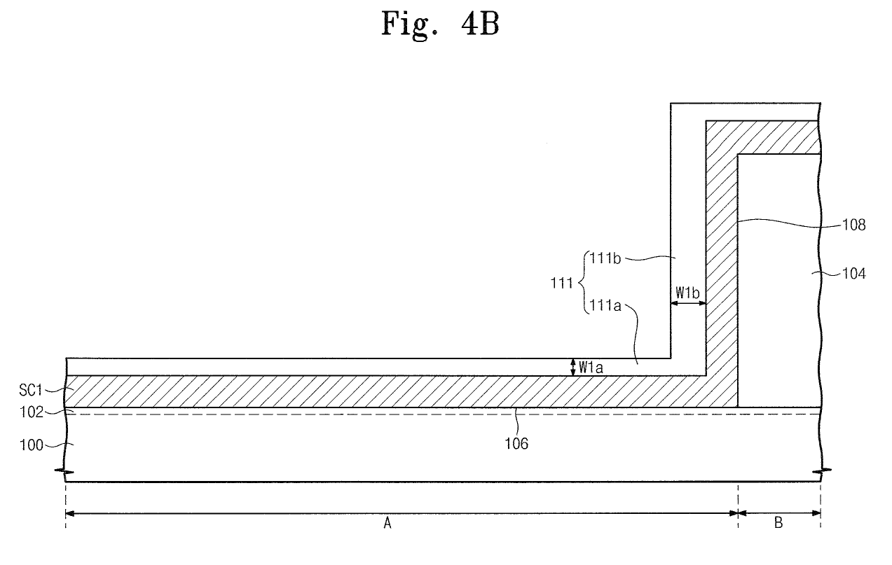

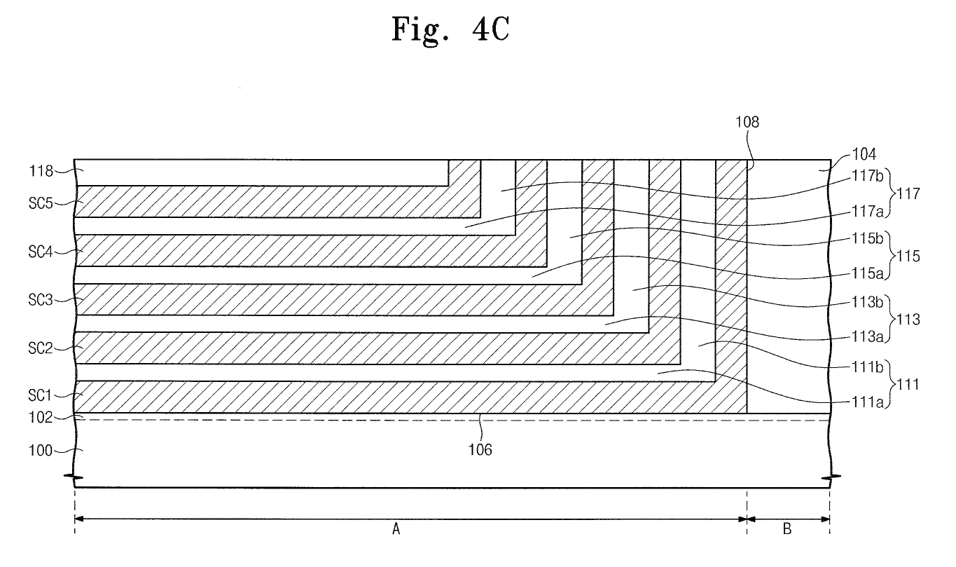

FIGS. 4A through 4C are cross-sectional views illustrating a method for forming a semiconductor device according to an embodiment

Referring to FIG. 4A, a first sacrificial layer SC1 may be formed on the substrate 100. A first intergate insulating layer 111 may be formed on the first sacrificial layer SC1. The first intergate insulating layer 111 may include a first intergate insulating layer flat portion 111a on the bottom surface 106 of the concave portion A of the substrate 100. The first intergate insulating layer 111 may include a first intergate insulating layer sidewall portion 111b extended over the sidewall 108 of the concave portion A from the first intergate insulating flat portion 111a.

Referring to FIG. 4B, an etching process may be performed on the first intergate insulating layer 111. The etching process may be an anisotropic etching process. An upper portion of the first intergate insulating layer flat portion 111a may be removed by the etching process. The remaining first intergate insulating layer flat portion 111a may have a thickness smaller than a thickness of the first intergate insulating layer sidewall portion 111b.

Referring to FIG. 4C, as described in FIG. 4B, insulating layers 111, 113, 115, and 117 sacrificial layers SC1 to SC5 may be alternately stacked. The insulating layers 111, 113, 115, and 117 may be spaced from each other by the sacrificial layer SC1 to SC5. The insulating layers 111, 113, 115, and 117 may include insulating layer flat portions 111a, 113a, 115a, and 117a over the bottom surface 106 of the concave portion A of the substrate 100. The insulating layers 111, 113, 115, and 117 may include insulating sidewall portions 111b, 113b, 115b, and 117b extended over the side surface 108 of the concave portion A from the insulating layer flat portions 111a, 113a, 115a, and 117a. The insulating layer sidewall portions 111b, 113b, 115b, and 117b may have a thickness greater than a thickness of the insulating layer flat portions 111a, 113a, 115a, and 117a. A string select insulating layer 118 may be formed on the sacrificial layer SC5. A planarization process may be performed using the string select insulating layer 118 as an etch stop layer. Thereafter, the method according to this embodiment may be provided by the method described in connection with FIGS. 2 and 3D through 3G.

Hereinafter, a semiconductor according to an embodiment will be described in detail.

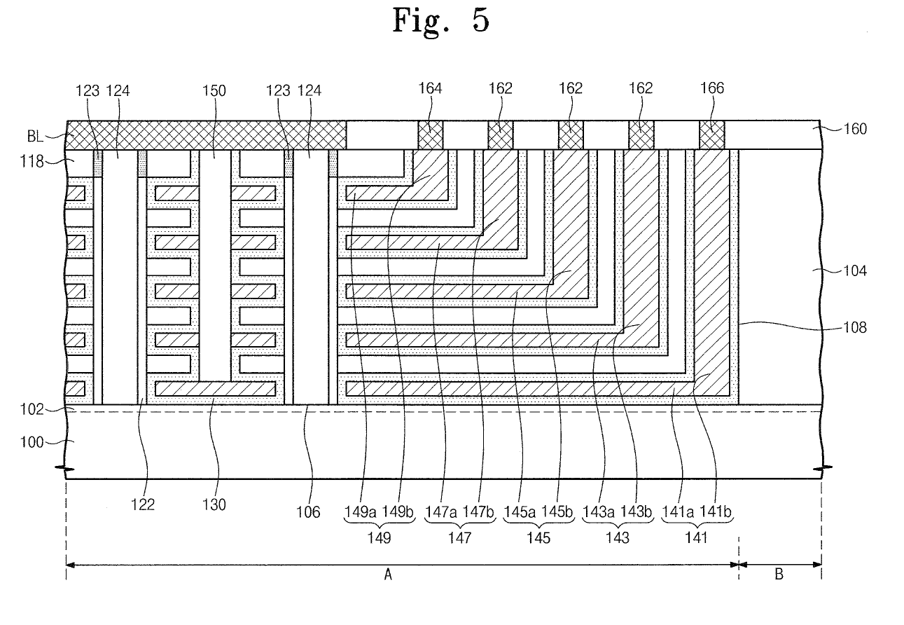

FIG. 5 is cross-sectional view illustrating a method for forming a semiconductor device according to an embodiment, which is taken along line I-P of FIG. 1.

Referring to FIGS. 1 and 5, material layers may be disposed on a substrate 100 to be spaced from each other. The material layers may include materials having conductivity. The material layers may be gate patterns 141, 143, 145, 147, and 149. The gate patterns 141, 143, 145, 147, and 149 may include gate pattern flat portions 141a, 143a, 145a, 147a, and 149a over a bottom surface 106 of a concave portion A of the substrate 100. The gate patterns 141, 143, 145, 147, and 149 may include gate pattern sidewall portions 141b, 143b, 145b, 147b, and 149b extended over a sidewall 108 of the concave portion A from the gate pattern flat portions 141a, 143a, 145a, 147a, and 149a. At least one of the gate pattern sidewall portions 141b, 143b, 145b, 147b, and 149b may have a thickness greater than a thickness of the gate pattern flat portions 141a, 143a, 145a, 147a, and 149a. Conductive patterns 162, 164, and 166 may be provided on the upper surfaces of the gate pattern sidewall portions 141b, 143b, 145b, 147b, and 149b. The conductive patterns 162, 164, and 166 may have a width smaller than a width of the gate pattern sidewall portions 141b, 143b, 145b, 147b, and 149b.

Similarly to the method described in connection with FIG. 2, cell gate patterns 143, 145, and 147, a string select gate pattern 149, a ground select gate pattern 141, insulating layers 111, 113, 115, and 117, a string select insulating layer 180, a bit line BL, an active pillar 122, a drain region 123, an insulating material 124, a protruded portion B, an insulating layer 104, a gapfill insulating layer 150, an interlayer dielectric layer 160, a common source region 102, and an information storage layer 130 may be provided.

Hereinafter, a method for forming a semiconductor device according to an embodiment will be described in detail.

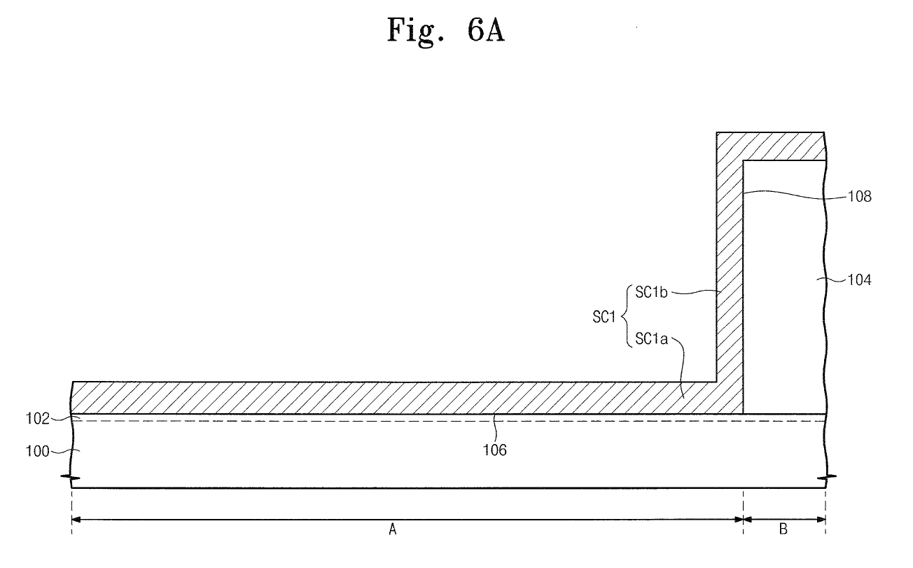

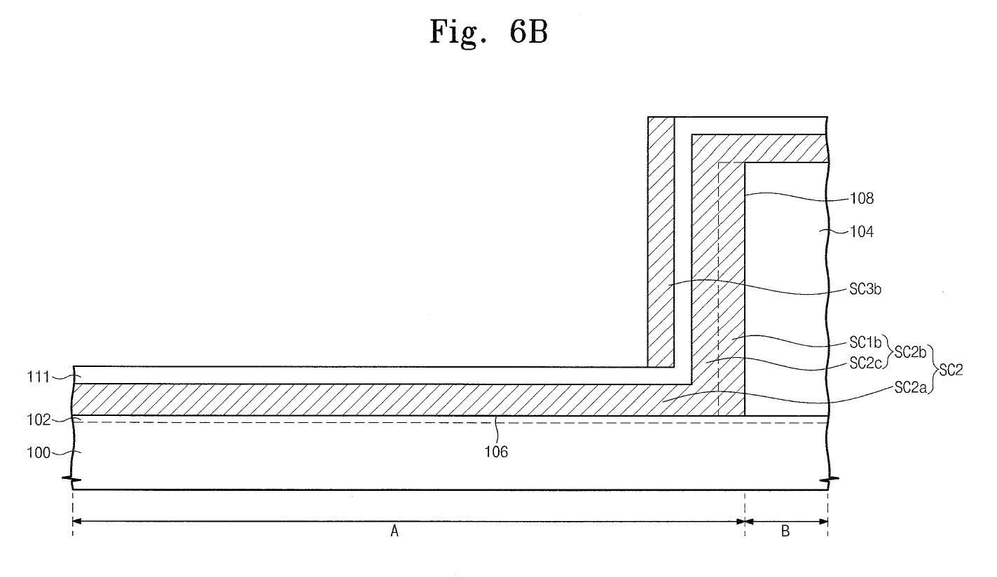

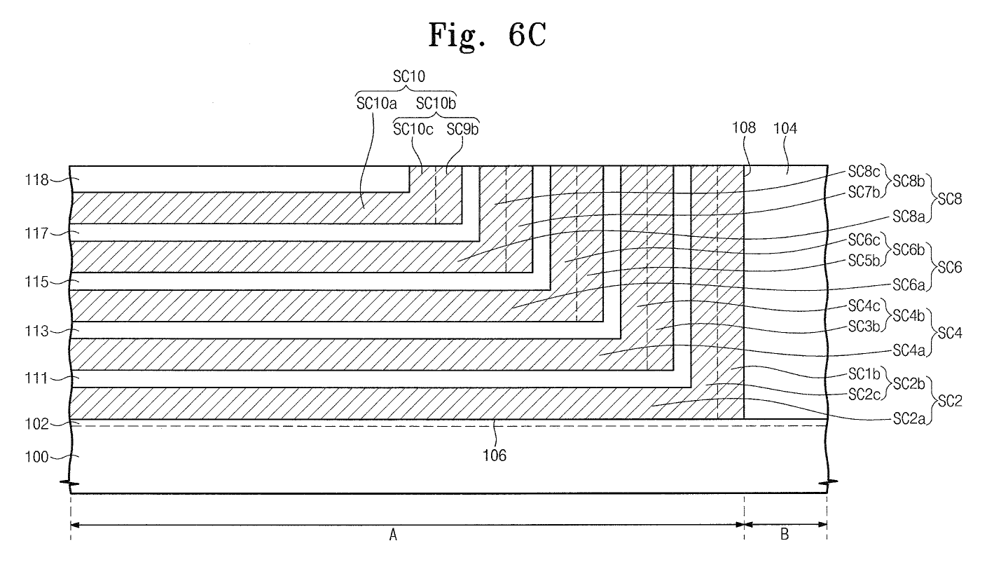

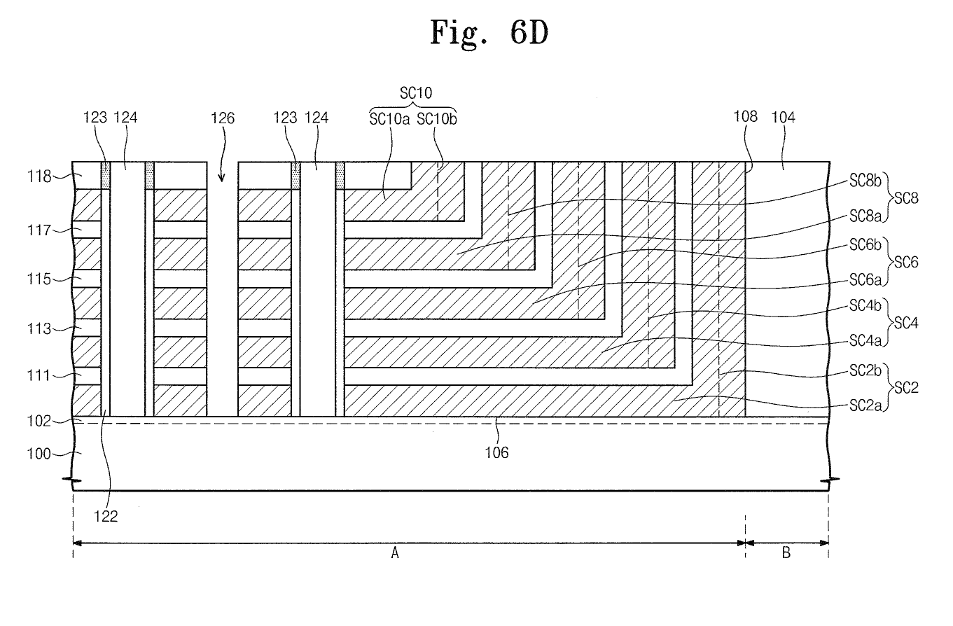

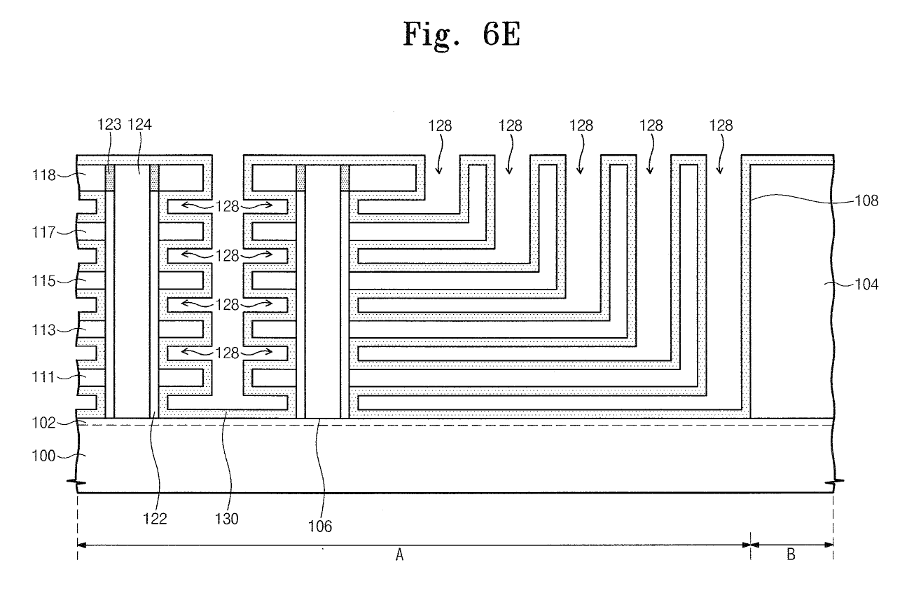

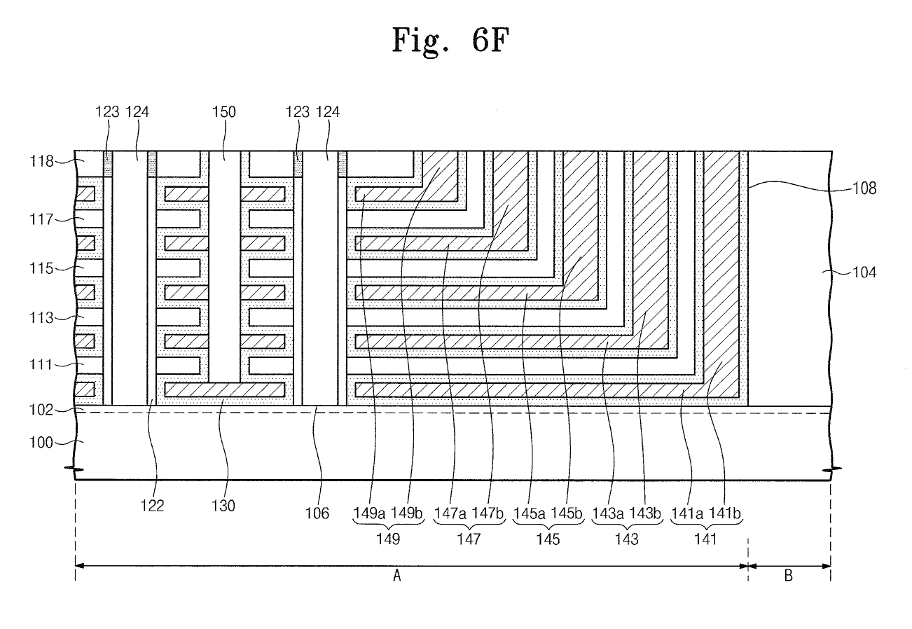

FIGS. 6A through 6F are cross-sectional views illustrating a method for forming a semiconductor device according to an embodiment

Referring to FIG. 6A, a first auxiliary sacrificial layer SC1 may be formed on the substrate 100 as described in connection with FIG. 3A. The first auxiliary sacrificial layer SC1 may be formed on the bottom surface 106 and the side surface 108 of the concave portion A. The first auxiliary sacrificial layer SC1 may also be formed on the protruded portion B. The first auxiliary sacrificial layer SC1 may include a first auxiliary sacrificial layer flat portion SC1a on the bottom surface 106 of the concave portion A, and a first auxiliary sacrificial layer sidewall portion SC1b extended over the side surface 108 of the concave portion A from the first auxiliary sacrificial layer flat portion SC1a.

Referring to FIG. 6B, an etching process may be performed on the first auxiliary sacrificial layer SC1 using the substrate 100 as an etch stop layer. The etching process may be an anisotropic etching process. Due to the etching process, the first auxiliary sacrificial flat portion SC1a may be removed, and the first auxiliary sacrificial sidewall portion SC1b may be remained.

After the etching process, a second sacrificial layer SC2 may be formed over the substrate 100. The second sacrificial layer SC2 may include a second sacrificial layer flat portion SC2a over the bottom surface 106 of the concave portion A of the substrate 100. The second sacrificial layer SC2 may include a second sacrificial layer sidewall portion SC2b extended over the side surface 108 of the concave portion A from the second sacrificial layer flat portion SC2a. The second sacrificial layer sidewall portion SC2b may include a main second sacrificial layer sidewall portion SC2c provided by the same process as performed on the second sacrificial layer flat portion SC2a, and the first auxiliary sacrificial layer sidewall portion SC1b contacting the main second sacrificial layer sidewall portion SC2c.

A first intergate insulating layer 111 may be formed on the second sacrificial layer SC2. A third sacrificial layer may be formed on the first intergate insulating layer 111. The third sacrificial layer may be anisotropically etched using the first intergate insulating layer 111 as an etch stop layer to form a third sacrificial layer sidewall portion SC3b.

Referring to FIG. 6C, sacrificial layers SC2, SC4, SC6, SC8, and SC10 and insulating layers 111, 113, 115, and 117 may be alternately formed over the substrate 100 by the method described in connection with FIG. 6B. The sacrificial layers SC2, SC4, SC6, SC8, and SC10 may include sacrificial layer flat portions SC2a, SC4a, SC6a, SC8a, and SC10, respectively, over the bottom surface of the concave portion A of the substrate 100. The sacrificial layers SC2, SC4, SC6, SC8, and SC10 may include sacrificial layer sidewall portions SC2b, SC4b, SC6b, SC8b, and SC10b, respectively, extended over the side surface 108 of the concave portion A from the sacrificial layer flat portions SC2a, SC4a, SC6a, SC8a, and SC10a, respectively. The sacrificial layer sidewall portions SC2b, SC4b, SC6b, SC8b, and SC10b may include main sacrificial sidewall portions SC2c, SC4c, SC6c, SC8c, and SC10c, respectively, provided by the same process as performed on the sacrificial layer flat portions SC2a, SC4a, SC6a, SC8a, and SC10a, and auxiliary sacrificial layer sidewall portions SC1b, SC3b, SCSb, SC7b, and SC9b, respectively, contacting the main sacrificial sidewall portions SC2c, SC4c, SC6c, SC8c, and SC10c, respectively. A string select insulating layer 118 may be formed on the tenth sacrificial layer SC10. A planarization process may be performed using the upper surface of the insulating layer 104 of the protruded portion A as an etch stop layer.

The insulating layers 111, 113, 115, and 117 may include a silicon oxide. The sacrificial layers SC2, SC4, SC6, SC8, and SC10 and the auxiliary sacrificial layers SC1, SC3, SC5, SC7, and SC9 may be formed of materials that can be selectively etched while minimally etching the insulating layers 111, 113, 115, and 117. For example, the sacrificial layers SC2, SC4, SC6, SC8, and SC10 and the auxiliary sacrificial layers SC1, SC3, SC5, SC7, and SC9 may include a silicon nitride.

Referring to FIG. 6D, an active pillar 122, an insulating material 124, a drain region 123, and a preliminary gate isolation region 126 may be provided by the method described in connection with FIGS. 3D through 3E.

Referring to FIG. 6E, the sacrificial layers SC2, SC4, SC6, SC8, and SC10 may be removed, and then gate regions 128 may be formed as described in the method of FIG. 3F. After removing the sacrificial layers SC2, SC4, SC6, SC8, and SC10, an information storage layer 130 may be formed by the method described in connection with FIG. 3G.

Referring to FIG. 6F, a preliminary gate conductive layer (not shown) may be formed to fill the preliminary gate isolation region 126 and the gate region 128 by the method described in connection with FIG. 3G. As described in connection with FIG. 2, portions of the information storage layer 130 and the preliminary gate conductive layer 140 may be removed. The preliminary gate conductive layer over the preliminary gate isolation region 126 may be removed, and then a gapfill insulating layer 150 may be formed over the resulting structure to form gate patterns 141, 143, 145, 147, and 149. As described in connection with FIG. 2, interlayer dielectric layer 160, conductive patterns 162, 164, and 166, and bit line BL may be provided.

Hereinafter, a method for forming a semiconductor device according to an embodiment will be described in detail.

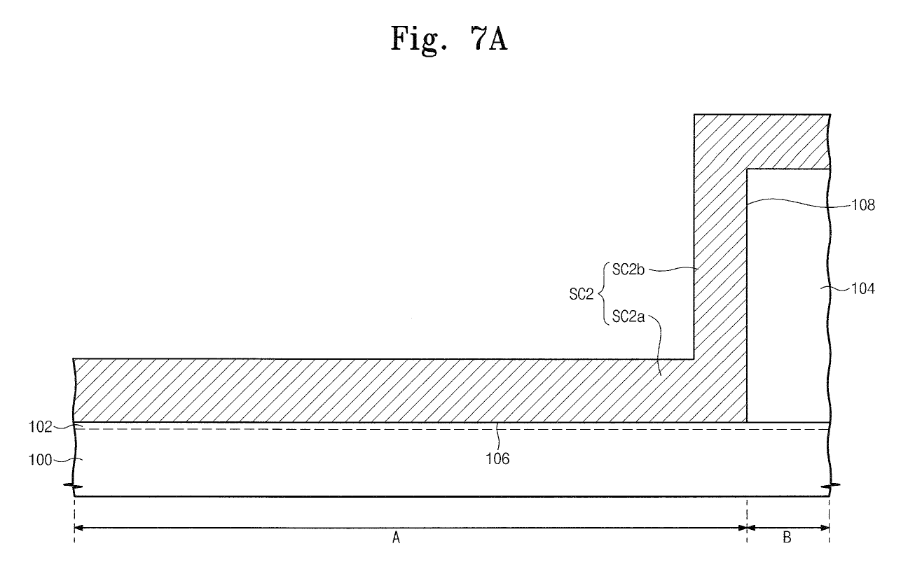

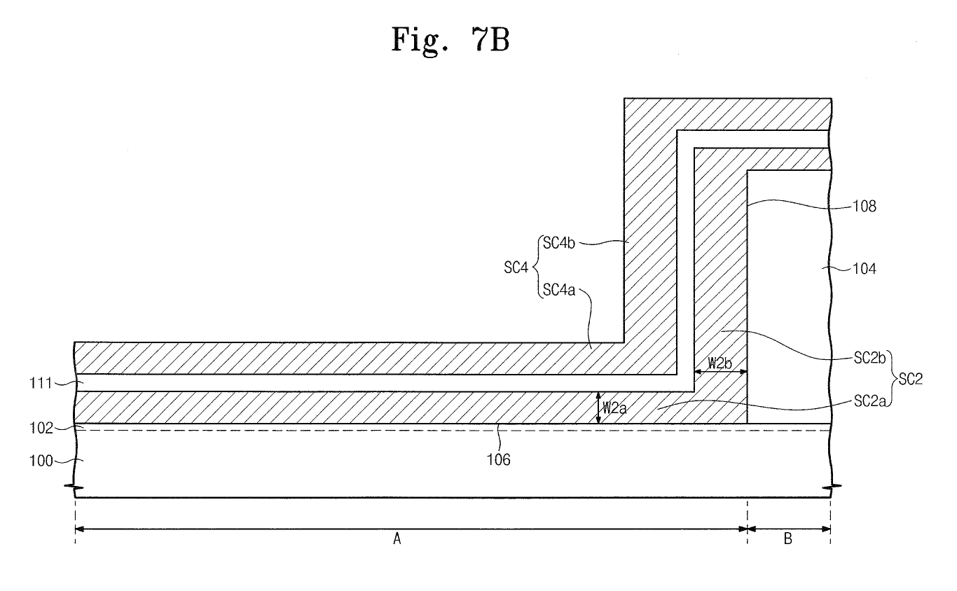

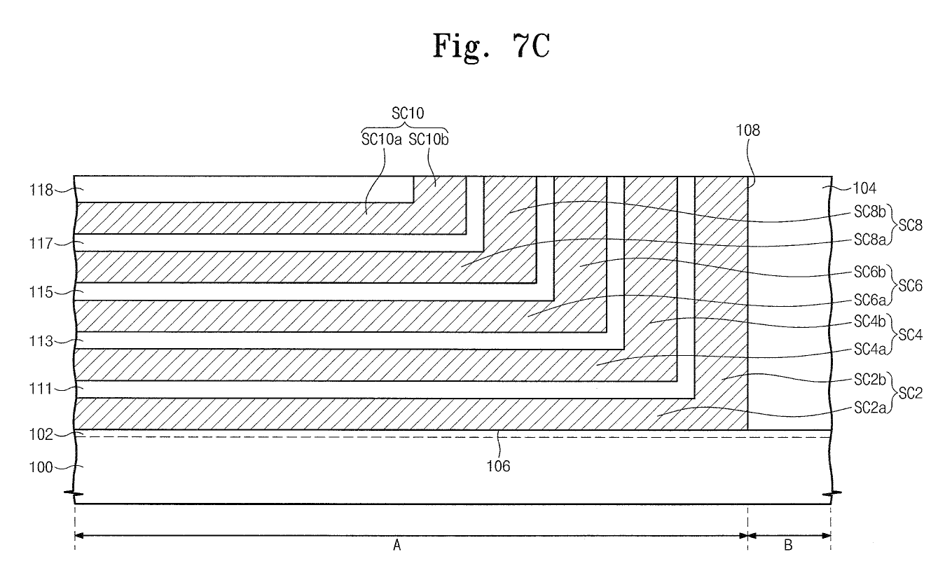

FIGS. 7A through 7C are cross-sectional views illustrating a method for forming a semiconductor device according to an embodiment

Referring to FIG. 7A, a second sacrificial layer SC2 may be formed on the substrate 100. The second sacrificial layer SC2 may include a second sacrificial layer flat portion SC2a over the upper surface 106 of a concave portion A of the substrate 100. The second sacrificial layer SC2 may include a second sacrificial layer sidewall portion SC2b extended over the side surface 108 of the concave portion A from the second sacrificial layer flat portion SC2a.

Referring to FIG. 7B, an etching processing may be performed on the second sacrificial layer SC2. The etching process may be an anisotropic etching process. A portion of the second sacrificial layer SC2a may be removed by the etching process. The second sacrificial layer flat portion SC2a may have a thickness W2a smaller than a thickness W2b of the second sacrificial layer sidewall portion SC2b. A first intergate insulating layer 111 and a fourth sacrificial layer SC4 may be sequentially formed over the second sacrificial layer SC2. The fourth sacrificial layer SC4 may be etched by an anisotropic etching process. A portion of a fourth sacrificial layer flat portion SC4a may be removed. The fourth sacrificial layer flat portion SC4a may have a thickness smaller than a thickness of the fourth sacrificial layer sidewall portion SC4b.

Referring to FIG. 7C, a sixth sacrificial layer SC6, an eighth sacrificial layer SC8, and a tenth sacrificial layer SC10 may be formed by the method described in connection with FIG. 7B. The sacrificial layers SC2, SC4, SC6, SC8, and SC10 may be spaced by the insulating layers 111, 113, 115, and 117. The sacrificial layers SC2, SC4, SC6, SC8, and SC10 may include sacrificial layer flat portions SC2a, SC4a, SC6a, SC8a, and SC10a, respectively, over the bottom surface 106 of the concave portions A of the substrate 100. The sacrificial layers SC2, SC4, SC6, SC8, and SC10 may include sacrificial layer sidewall portions SC2b, SC4b, SC6b, SC8b, and SC10b, respectively, extended over the side surface 108 of the concave portion A from the sacrificial layer flat portions SC2a, SC4a, SC6a, SC8a, and SC10a, respectively. The sacrificial layer sidewall portions SC2b, SC4b, SC6b, SC8b, and SC10b may have a thickness greater than a thickness of the sacrificial layer flat portions SC2a, SC4a, SC6a, SC8a, and SC10a. A string select insulating layer 118 may be formed on the tenth sacrificial layer SC10. A planarization process may be performed using a top surface of the protruded portion B as an etch stop layer. Thereafter, the method according to this embodiment may be provided by the method described in connection with FIGS. 6D through 6F.

Hereinafter, a semiconductor device according to an embodiment will be described in detail.

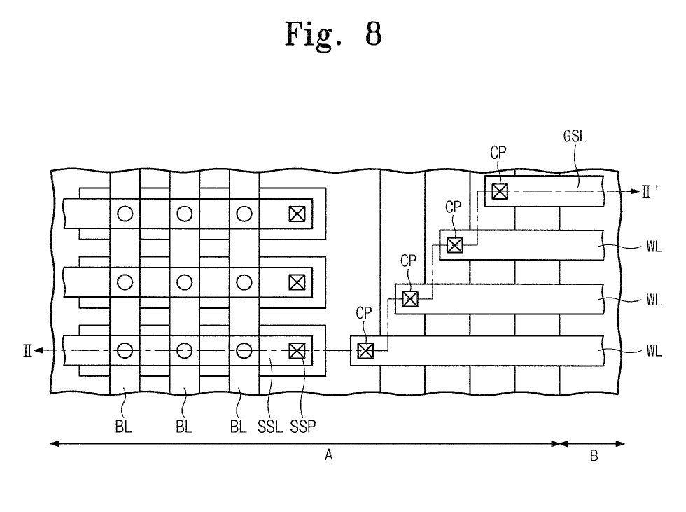

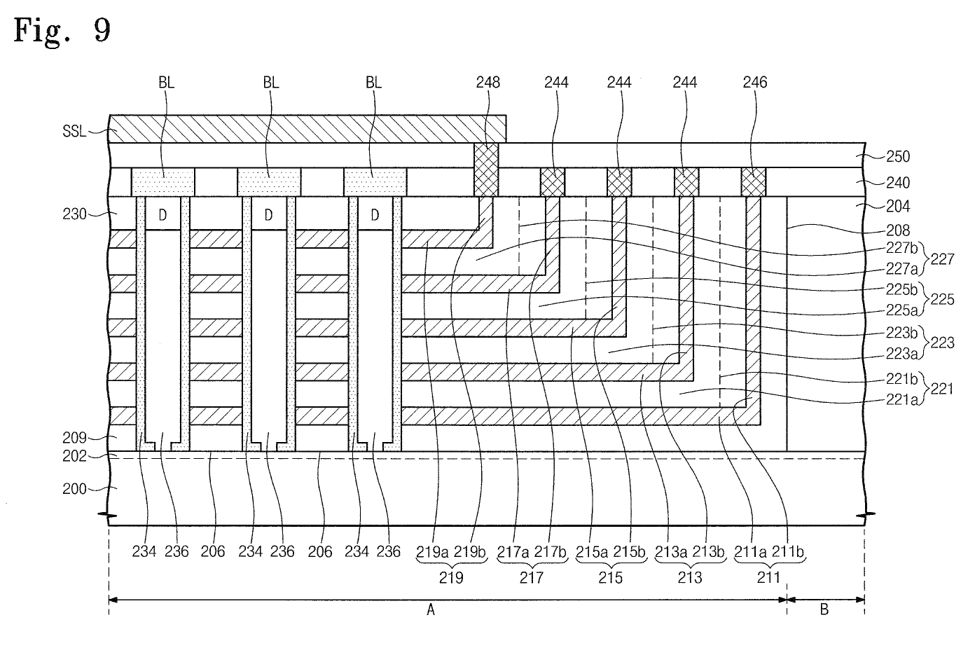

FIG. 8 is a plan view illustrating a semiconductor device according to an embodiment. FIG. 9 is a cross-sectional view illustrating a semiconductor device according to an embodiment. FIG. 9 is a cross-sectional view taken along line II-II′ of FIG. 8.

Referring to FIGS. 8 and 9, a substrate 200 may be provided. The substrate 200 may be a semiconductor-based substrate. The substrate 200 may include a well. The well may include a first conductive type dopant.

The substrate 200 may include a concave portion A having a bottom surface 206 and a side surface 208, and a protruded portion B extended from the side surface 208. An insulating layer 204 may be disposed on the substrate 200 to define the concave portion A and the protruded portion B. The insulating layer 204 may include a silicon oxide. In contrast, the protruded portion A of the substrate 200 may be defined by etching the substrate 200. In this case, the concave portion A and the protruded portion B may be one body substrate.

An active pillar 236 may be disposed to be upwardly extended from the bottom surface 206 of the concave portion A of the substrate 200. The active pillar 122 may be extended perpendicular to the substrate 200. The active pillar 236 may be connected to the substrate 200 at one end thereof. The active pillar 236 may be connected to a bit line BL at the other end thereof. The active pillar 236 may include a single or polycrystal semiconductor.

A common source region 202 may be disposed on the substrate 200 to be electrically connected to the active pillar 236. The common source region 202 may be disposed to have a plate form in a cell region of the substrate 200. The common source region 202 may include a high-concentration of dopant. The dopant included in the common source region 202 may be a second conductive type dopant different from a dopant included in the well. For example, when the well includes a p-type dopant, the common source region 202 may include an n-type dopant.

Material layers may be disposed on the substrate 200 to be spaced from each other. The material layers may include materials having insulating properties. The material layers may include inter-cell gate insulating layers 223 and 225, a first intergate insulating layer 221, and a second intergate insulating layer 227. The insulating layers 221, 223, 225, and 227 may include insulating layer flat portions 221a, 223a, 225a, and 227a, respectively, on the bottom surface 206, and insulating layer sidewall portions 221b, 223b, 225b, and 227b, respectively, extended over the side surface 208 from the insulating layer flat portions 221a, 223a, 225a, and 227a, respectively. At least one of the insulating layer sidewall portions 221b, 223b, 225b, and 227b may have a thickness greater than a thickness of the insulating layer flat portions 221a, 223a, 225a, and 227a. The insulating layer sidewall portions 221b, 223b, 225b, and 227b may have a width greater than an interval between the insulating layers 221, 223, 225, and 227. For example, a width of the insulating layer sidewall portion 221b, 223b, 225b, and 227b may be greater than an interval between the insulating layers 221 and 223; between the insulating layers 223 and 225 or between the insulating layers 223 and 221; between the insulating layers 225 and 227 or between the insulating layers 225 and 223; and between the insulating layers 227 and 225, respectively. A string select insulating layer 209 may be disposed between the substrate 200 and the first intergate insulating layer 221.

Gate patterns 211, 213, 215, 217, and 219 may include the gate pattern flat portions 211a, 213a, 215a, 217a, and 219a, respectively, and the gate pattern sidewall portions 211b, 213b, 215b, 217b, and 219b, respectively. The gate patterns 211, 213, 215, 217, and 219 may include cell gate patterns 213, 215, and 217, a ground select gate pattern 211, and a string select gate pattern 219. The gate patterns 211, 213, 215, 217, and 219 may be spaced from each other by the insulating layers 221, 223, 225, and 227.

Gate pattern flat portions 211a, 213a, 215a, 217a, and 219a may be disposed between the first intergate insulating flat portion 221a and the bottom surface 206 of the substrate 200, between the insulating layer flat portions 221a, 223a, 225a, and 227a, and between the second intergate insulating layer flat portion 227a and the string select insulating layer 230.

Gate pattern sidewall portions 211b, 213b, 215b, 217b, and 219b may be disposed between the first intergate insulating layer sidewall portion 221b and the side surface 208 of the substrate 200, between the insulating layer sidewall portions 221b, 223b, 225b, and 227b, and between the second intergate insulating layer sidewall portion 227b and the string select insulating layer 230.

The upper surfaces of the gate pattern sidewall portions 211b, 213b, 215b, 217b, and 219b may be coplanar with the upper surface of the insulating layer 204 of the protruded portion B. The lower surface of the insulating layer 204 of the protruded portion B may be coplanar with the bottom surface 206 of the concave portion A.

The active pillar 236 may pass through the gate patterns 211, 213, 215, 217, and 219 and be connected to the substrate 200. The gate patterns 211, 213, 215, 217, and 219 stacked along the sidewall of the active pillar 236 may form one vertical type cell string. The cell gate patterns 213, 215, and 217 may have a plate form parallel to the substrate 200. Although three cell gate patterns 213, 215, and 217 are shown in the accompanying drawing for convenience of explanation, the number of the cell gate patterns is not limited thereto.

An information storage layer 234 may be disposed between the cell gate patterns 213, 215, and 217 and the active pillar 236. The information storage layer 234 may be formed to have a cylindrical shape passing through the cell gate patterns 213, 215, and 217 and the select gate patterns 211 and 219. The information storage layer 234 may be formed to surround the active pillar 236. The information storage layer 234 may include a tunnel dielectric layer, a trap insulating layer, and a blocking layer.

The tunnel dielectric layer may be a single layer or a multilayer structure. For example, the tunnel dielectric layer may include at least one of silicon oxynitride, silicon nitride, silicon oxide, and metal oxide.

The trap insulating layer may include charge trap sites capable of storing electric charges. For example, the trap insulating layer may include at least one of silicon nitride, metal nitride, metal oxynitride, metal silicon oxide, metal silicon oxynitride, and nano dots.

The blocking layer may include at least one selected from a silicon oxide layer, a silicon nitride layer, a silicon oxynitride layer, and a high dielectric layer. The high dielectric layer may include at least one selected from a metal oxide, a metal nitride, and a metal oxynitride. The high electric layer may include Hafnium (Hf), Zirconium (Zr), Aluminum (Al), Tantalum (Ta), Lanthanum (La), Cerium (Ce), and Praseodymium (Pr). A dielectric constant of the blocking layer may be greater than a dielectric constant of the tunnel insulating layer.

The cell gate patterns 213, 215, and 217 may form word lines, respectively. First conductive patterns 244 may be provided on the upper surfaces of the cell gate pattern sidewall portions 213b, 215b, and 217b. The first conductive patterns 244 may have a width greater than a width of the cell gate pattern sidewall portions 213b, 215b, and 217b. The first conductive patterns 244 may be cell plugs CP. The word lines may be connected to the wide word lines WL by the cell plugs CP, respectively. In contrast, the first conductive patterns 244 may be the wide word lines WL.

The ground select gate pattern 211 may be disposed between the substrate 200 and the cell gate pattern 213 disposed at the lowest position thereof. The ground select gate pattern 211 may control electrical connection in the active pillar 236 and the substrate 200. A second conductive pattern 246 may be provided on the upper surface of the sidewall portion 211b of the ground select gate pattern 211. The second conductive pattern 246 may have a width greater than a width of the sidewall portion 211b of the ground select gate pattern 211. The second conductive pattern 246 may be a ground select plug GSP. The ground select gate pattern 211 may be connected to a ground select line GSL by the ground select plug GSP. In contrast, the second conductive pattern 246 may be a ground select line GSL.

The string select gate pattern 219 may be disposed over the cell gate pattern 217 disposed at the highest position of the cell gate patterns 213, 215 and 217. The string select gate pattern 219 may be extended in a first direction parallel to the substrate 200. A third conductive pattern 248 passing through the first interlayer dielectric layer 240 and the second interlayer dielectric layer 250 may be provided on the upper surface of the sidewall portion 219b of the string select gate pattern 219. The third conductive pattern 248 may have a width greater than a width of the sidewall portion 219b of the string gate pattern 219. The third conductive pattern 248 may be a string select plug SSP. The string select gate pattern 219 may be connected to a string select line SSL by the string select plug SSP.

A bit line BL may be disposed on the string select gate pattern 219. The bit line BL may be disposed to cross the string select gate pattern 219. The bit line BL may be extended in a second direction crossing the first direction in which the string select gate pattern 219 is extended. The first and second directions may be perpendicular to each other. The string select insulating layer 230 may be disposed between the string select gate pattern 219 and the bit line BL.

The bit line BL may be connected to the active pillar 236 via a drain region D located on the upper portion of the active pillar 236. The drain region D may be a high-concentration of dopant region. According to an embodiment, the bit line BL may be connected to the drain region D via a certain plug. A plurality of active pillars 236 may be disposed on the substrate 200. The electrical connection between the bit line BL and the active pillar 236 may be controlled by the string select gate pattern 219.

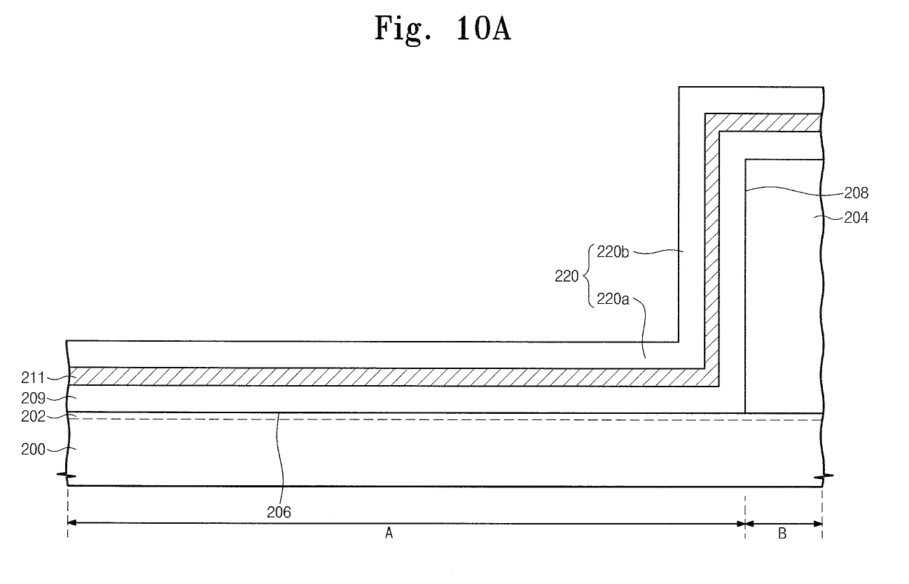

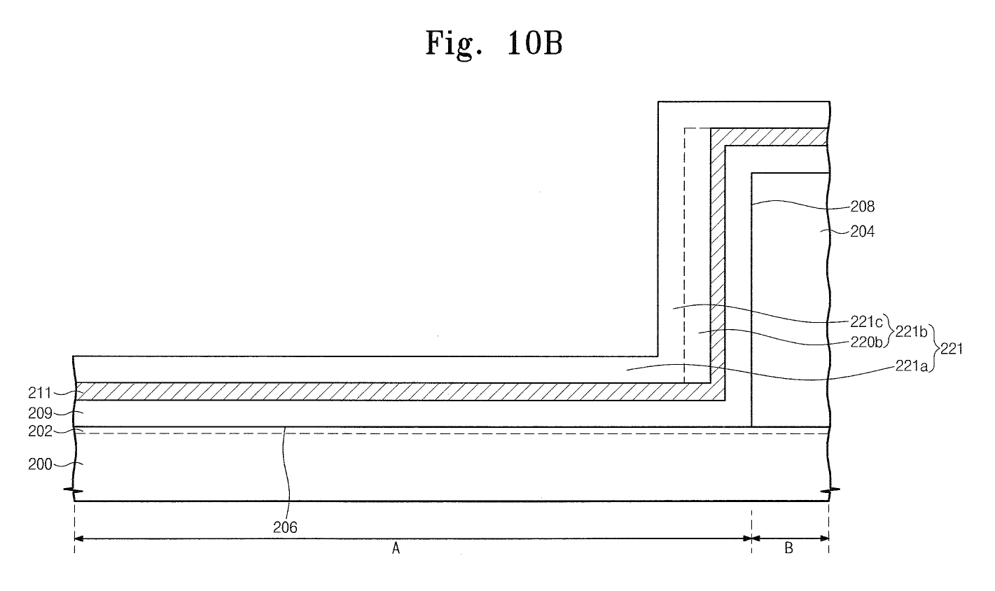

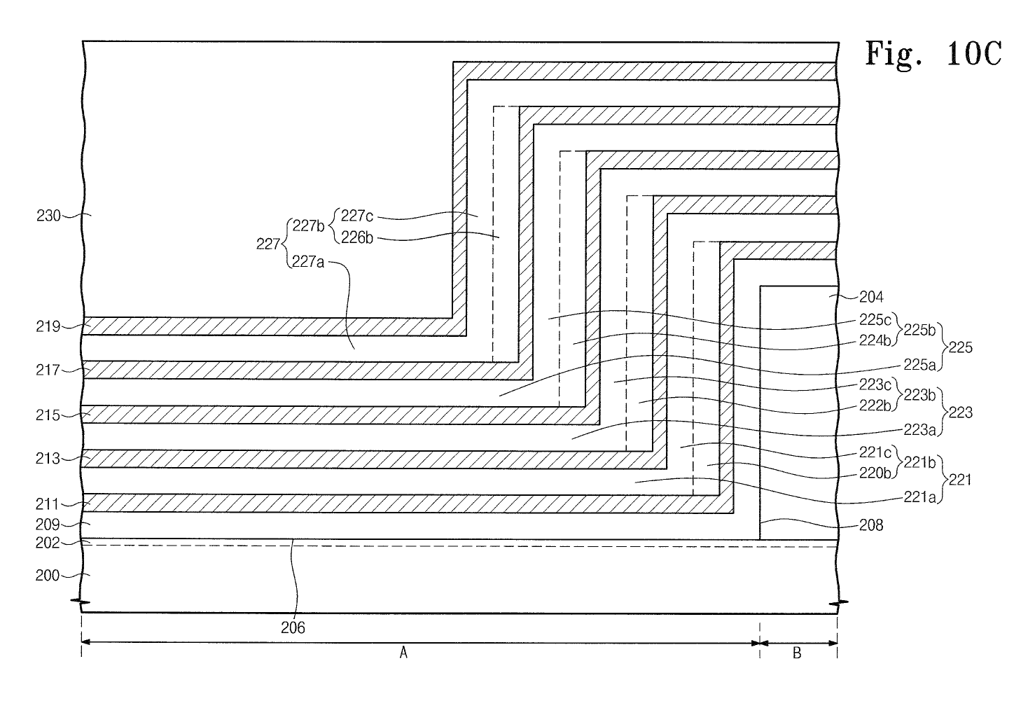

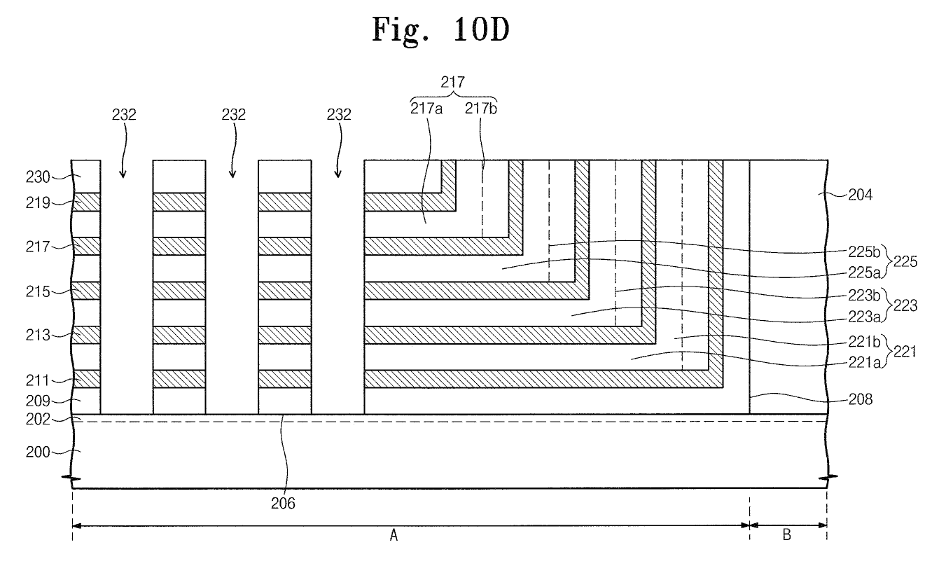

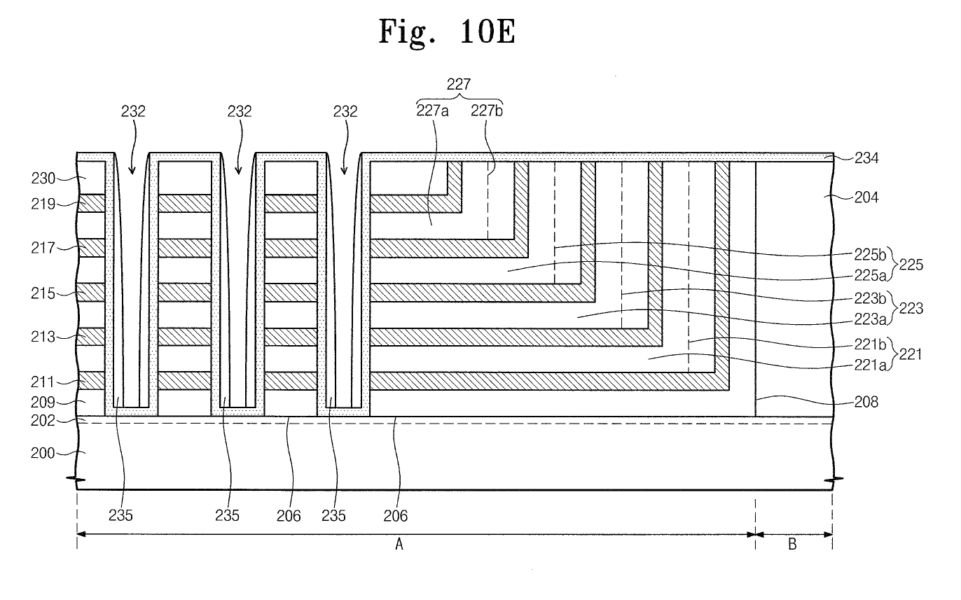

Hereinafter, a method for forming a semiconductor device according to an embodiment will be described in detail with reference to FIGS. 10A through 10F.

FIGS. 10A through 10F are cross-sectional views illustrating a method for forming a semiconductor device according to an embodiment

Referring to FIG. 10A, a substrate 100 may be provided. The substrate 200 may include a concave portion A having a bottom surface 206 and a side surface 208, and a protruded portion B extended from the side surface 208. An insulating layer 204 may be formed on the substrate 200 to form the concave portion A and the protruded portion B. The insulating layer 204 may include a silicon oxide. In contrast, the substrate 200 may be etched to form the concave portion A and the protruded portion B.

The substrate 200 may be a semiconductor (e.g., p-type silicon wafer) with a single crystal structure. The substrate 200 may include a well. The well may be formed by implanting a dopant into the substrate 200. The dopant may be implanted into the substrate 200 by a doping process including an ion implantation process or a plasma implantation process. A common source region 202 may be provided on the upper surface of the substrate 200. The common source region 202 may be formed by doping the well with a dopant. The common source region 202 may include a dopant of a conductive type different from the well. For example, the well may include a p-type dopant, and the common source region 202 may include an n-type dopant.

A ground select insulating layer 209 may be formed on the substrate 200. The ground select insulating layer 209 may be formed on the bottom surface 206 and the side surface 208 of the concave portion S of the substrate 200. A ground select gate pattern 211 may be formed on the ground select insulating layer 209. The ground select gate pattern 211 may be formed over the substrate 200. A first auxiliary intergate insulating layer 220 may be formed on the ground select gate pattern 211. The first auxiliary intergate insulating layer 220 may include a first auxiliary intergate insulating layer flat portion 220a formed on the bottom surface 206 of the concave portion A of the substrate 200. The first auxiliary integrate insulating layer 220 may include a first auxiliary intergate insulating sidewall portion 220b extended over the side surface 208 from the first auxiliary intergate insulating layer flat portion 220a.

Referring to FIG. 10B, an etching process may be performed on the first auxiliary intergate insulating layer 220 using the ground select insulating gate pattern 211 as an etch stop layer. The etching process may be an anisotropic etching process. Due to the etching process, the first auxiliary intergate insulating layer flat portion 220a may be removed, and the first auxiliary intergate insulating layer sidewall portion 220b may be remained.

After the etching process, a first intergate insulating layer 221 may be formed over the substrate 200. The first intergate insulating layer 221 may include a first intergate insulating layer flat portion 221a over the bottom surface 106 of the concave portion A of the substrate 200. The first intergate insulating layer 221 may include a first intergate insulating layer sidewall portion 221b extended over the side surface 208 of the concave portion A from the first intergate insulating layer flat portion 221a. The first intergate insulating layer sidewall portion 221b may include a main first intergate insulating layer sidewall portion 221c provided by the same process as performed on the first intergate insulating layer flat portion 221a, and the first auxiliary intergate insulating layer sidewall portion 220b contacting the main first intergate insulating layer sidewall portion 221c.

Referring to FIG. 10C, gate patterns 213, 215, 217, and 219 and insulating layers 223, 225, and 227 may be alternately formed over the first intergate insulating layer 221 by the method described in connection with FIG. 10B. A string select insulating layer 230 may be formed on the string select gate pattern 219.

The insulating layers 221, 223, 225, and 227 may include insulating layer flat portions 221a, 223a, 225a, and 227a, respectively, over the bottom surface 206 of the concave portion A of the substrate 200. The insulating layers 221, 223, 225, and 227 may include insulating layer sidewall portions 221b, 223b, 225b, and 227b, respectively, extended over the sidewall 208 of the concave portion A from the insulating layer flat portions 221a, 223a, 225a, and 227a, respectively. The insulating layer sidewall portions 221b, 223b, 225b, and 227b may include main insulating layer sidewall portions 221c, 223c, 225c, and 227c, respectively, provided by the same process as performed on the insulating layer flat portions 221a, 223a, 225a, and 227a, and auxiliary insulating layer sidewall portions 220b, 222b, 224b, and 226b, respectively, contacting the main insulating layer sidewall portions 221c, 223c, 225c, and 227c, respectively.

The gate patterns 221, 223, 225, 227, and 229 may include metal or polycrystal semiconductor materials. The ground select gate pattern 211 may be formed to have a plate form. In contrast, the plate form may be patterned to allow the ground select gate pattern 211 to have a linear form.

Referring to FIG. 10D, a planarization process may be performed using the upper surface of the protruded portion A as an etch stop layer. The planarization process may be performed by an etchback process or a Chemical Mechanical Polishing (CMP) process. A string select gate pattern 219 may be formed on the cell gate patterns 213, 215, and 217 in a linear form. The string select gate pattern 219 may have a linear form extending in a first direction. The gate patterns 211, 213, 215, 217, and 219, the insulating layers 221, 223, 225, and 227 between the gate patterns 211, 213, 215, 217, and 219, and the string select insulating layer 230 may be anisotropically etched to form an opening 232 exposing the common source region 202.

Referring to FIG. 10E, an information storage layer 234 may be formed to contact the sidewall of the gate patterns 211, 213, 215, 217, and 219, the sidewall of the insulating layers 221, 223, 225, and 227, and the sidewall of the string select insulating layer 230.

After the information storage layer 234 is formed, a spacer 235 may be formed in the opening 232. The spacer 235 may cover the information storage layer 234 on the sidewall and a portion of the information storage layer 234 on the bottom surface of the opening 232. The spacer 234 may comprise a semiconductor material.

Referring again to FIG. 9, the information storage layer 234 may be etched using the spacer 235 as an etch mask. Thus, the portion of the information storage layer 234 on the bottom surface of the opening 232 may be etched to expose a portion of the common source region 202.

An active pillar 236 may be formed to fill the opening 232. The active pillar 236 may include, but not limited to, a single crystal semiconductor. When the active pillar 236 includes a single crystal semiconductor, the active pillar 236 may be formed as a seed layer of the substrate 200 by an epitaxial growth process. In contrast, the active pillar 236 may be formed by phase-shifting a polycrystal or amorphous semiconductor layer using heat and/or laser after the polycrystal or amorphous semiconductor layer is formed to fill the opening 232. The active pillar 236 may be formed to fully fill the opening 232 as described above, or may be formed to have a cylindrical shape by removing a portion of the active pillar 236 filling the opening 232.

A drain region D may be formed on the active pillar 236. The drain region D may be formed by doping an upper portion of the active pillar 236. The drain region D may be a region heavily doped with dopant of a conductive type different from the well. For example, the drain region D may include a high-concentration of n-type dopant.

A first interlayer dielectric layer 240 may be formed over the substrate 200. The first interlayer dielectric layer 240 may be patterned to form openings exposing the upper surface of the gate pattern sidewall portions 211b, 213b, 215b, 217b, and 219b and the drain region D of the active pillar 236. First conductive patterns 244 and second conductive pattern 246 may be formed to fill the openings. A second interlayer dielectric layer 250 may be formed on the first interlayer dielectric layer 240. An opening may be formed to pass through the second interlayer dielectric layer 250, and a third conductive pattern 248 may be formed to fill the opening.

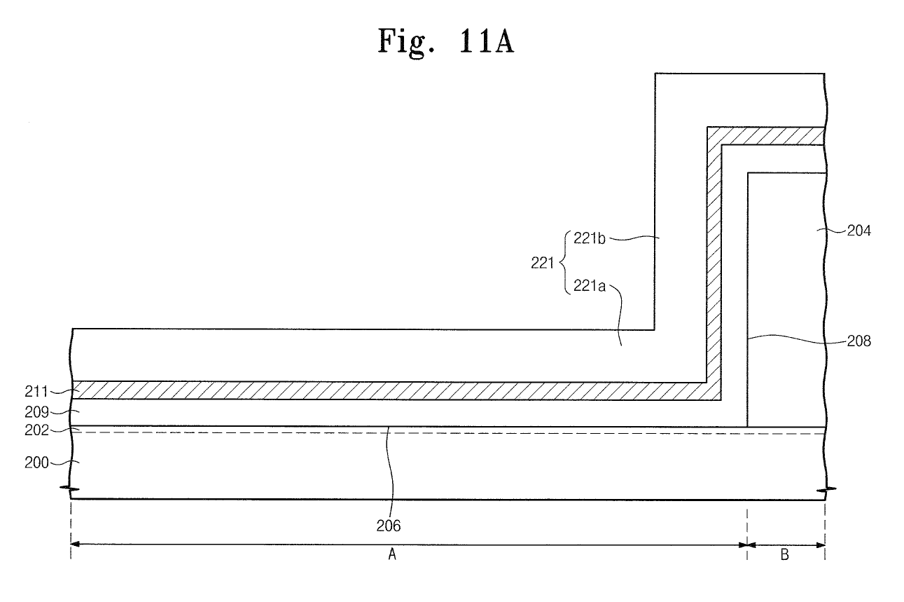

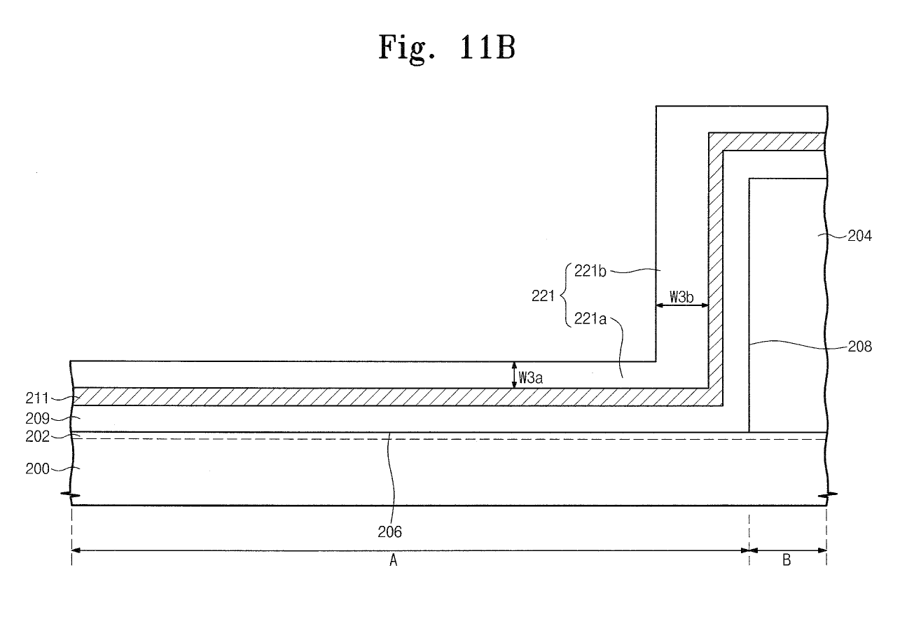

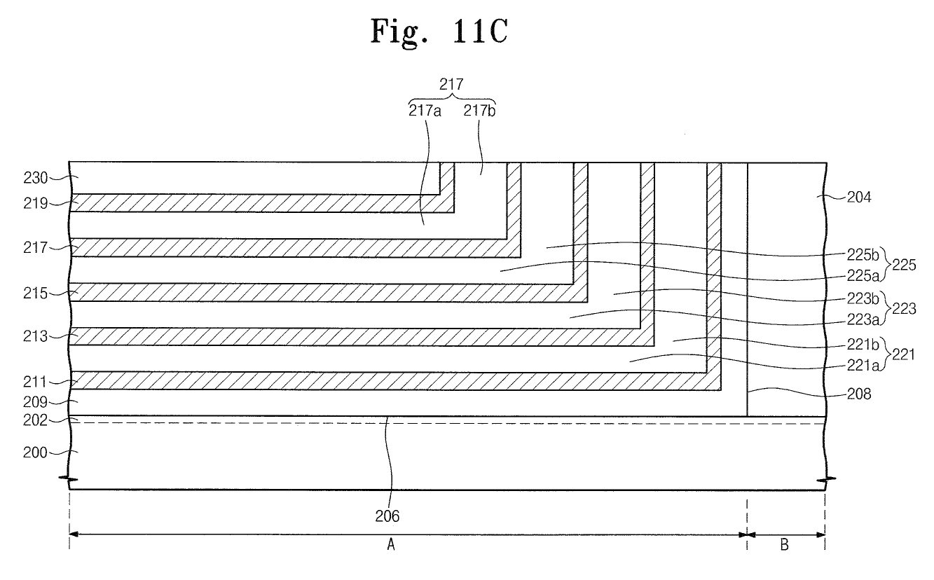

Hereinafter, a method for forming a semiconductor device according to an embodiment will be described with reference to FIGS. 11A through 11C.

FIGS. 11A through 11C are cross-sectional views illustrating a method for forming a semiconductor device according to an embodiment

Referring to FIG. 11A, a ground select insulating layer 209 and a ground select gate pattern 211 may be sequentially formed on the substrate 200. A first intergate insulating layer 221 may be formed on the ground select gate pattern 211. The first intergate insulating layer 221 may include a first intergate insulating flat portion 221a on the bottom surface of a concave portion A of the substrate 200. The first intergate insulating layer 221 may include a first intergate insulating layer sidewall portion 221b extended over the side surface of the concave portion A from the first intergate insulating flat portion 221a. The first intergate insulating layer 221 may also be formed on a protruded portion B.

Referring to FIG. 11B, an etching process may be performed on the first intergate insulating layer 221. The etching process may be an anisotropic etching process. Due to the etching process, a portion of the first intergate insulating layer flat portion 221a may be removed. The first intergate insulating layer flat portion 221a may have a thickness W3a smaller than a thickness W3b of the first intergate insulating layer sidewall portion 221b.

Referring to FIG. 11C, gate patterns 211, 213, 215, 217, and 219 and insulating layers 221, 223, 225, and 227 may be alternately stacked over the substrate 200 by the method described in connection with FIG. 11B. The insulating layers 221, 223, 225, and 227 may include insulating layer flat portions 221a, 223a, 225a, and 227a, respectively, on the bottom surface 206 of the concave portion A of the substrate 200. The insulating layers 221, 223, 225, and 227 may include insulating layer sidewall portions 221b, 223b, 225b, and 227b, respectively, extended over the side surface 208 of the concave portion A from the insulating layer flat portions 221a, 223a, 225a, and 227a, respectively. The insulating layer sidewall portions 221b, 223b, 225b, and 227b may have a thickness greater than a thickness of the insulating layer flat portions 221a, 223a, 225a, and 227a. A string select insulating layer 230 may be formed on the string select gate pattern 219. A planarization process may be performed using the upper surface of the protruded portion B as an etch stop layer. Thereafter, the method according to this embodiment may be provided by the method described in connection with FIGS. 9, and 10D and 10E.

Hereinafter, a semiconductor device according to an embodiment will be described in detail.

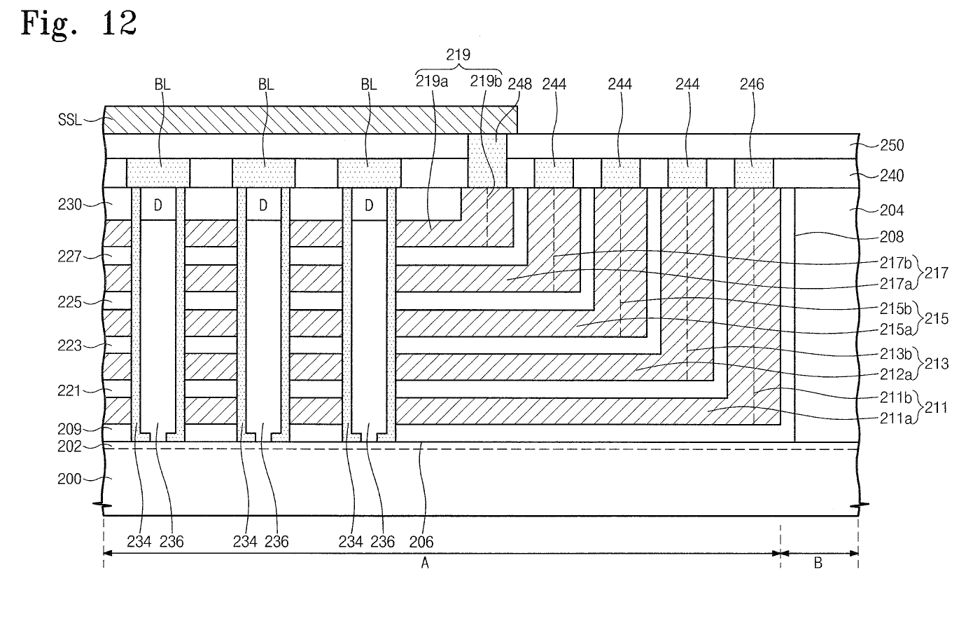

FIG. 12 is a cross-sectional view illustrating a method for forming a semiconductor device according to an embodiment, which is taken along line II-IP of FIG. 8.

Referring to FIGS. 8 and 12, material layers may be disposed on a substrate 200 to be spaced from each other. The material layers may include materials having conductivity. The material layers may be gate patterns 211, 213, 215, 217, and 219. The gate patterns 211, 213, 215, 217, and 219 may include gate pattern flat portions 211a, 213a, 215a, 217a, and 219a, respectively, over a bottom surface 206 of a concave portion A of the substrate 200. The gate patterns 211, 213, 215, 217, and 219 may include gate pattern sidewall portions 211b, 213b, 215b, 217b, and 219b, respectively, extended over a sidewall 208 of the concave portion A from the gate pattern flat portions 211a, 213a, 215a, 217a, and 219a, respectively. At least one of the gate pattern sidewall portions 211b, 213b, 215b, 217b, and 219b may have a thickness greater than a thickness of the gate pattern flat portions 211a, 213a, 215a, 217a, and 219a. Conductive patterns 244, 246, and 248 may be provided on the upper surfaces of the gate pattern sidewall portions 211b, 213b, 215b, 217b, and 219b. The conductive patterns 244, 246, and 248 may have a width smaller than a width of the gate pattern sidewall portions 211b, 213b, 215b, 217b, and 219b.

As described in FIG. 9, cell gate patterns 213, 215, and 217, a ground select gate pattern 211, a string select gate pattern 219, insulating layers 221, 223, 225, and 227, a string select insulating layer 209, a bit line BL, an active pillar 236, an information storage layer 234, a first interlayer dielectric layer 240, a second interlayer dielectric layer 250, an insulating layer 204, a common source region 202, and a drain region D may be provided.

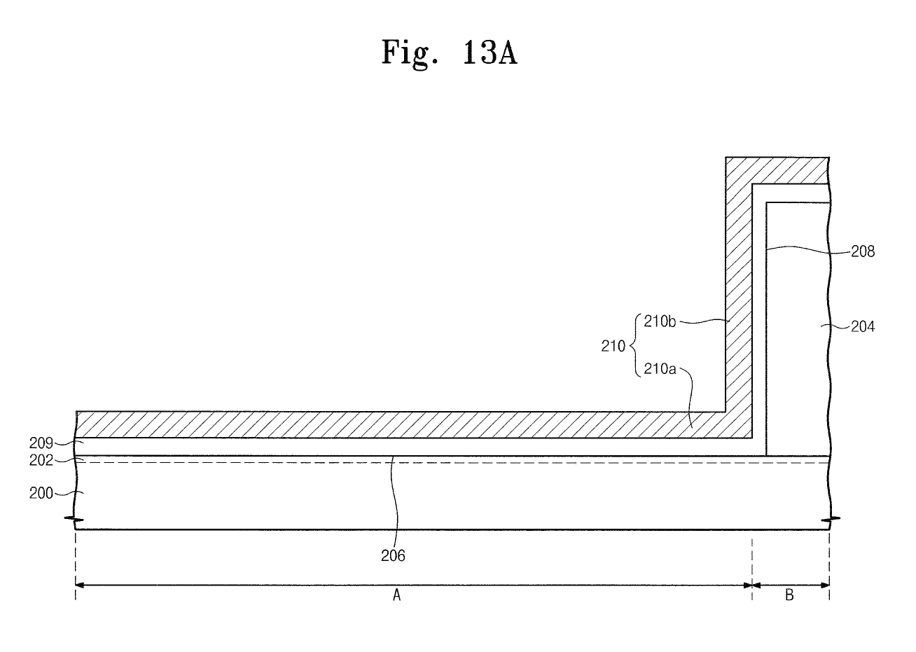

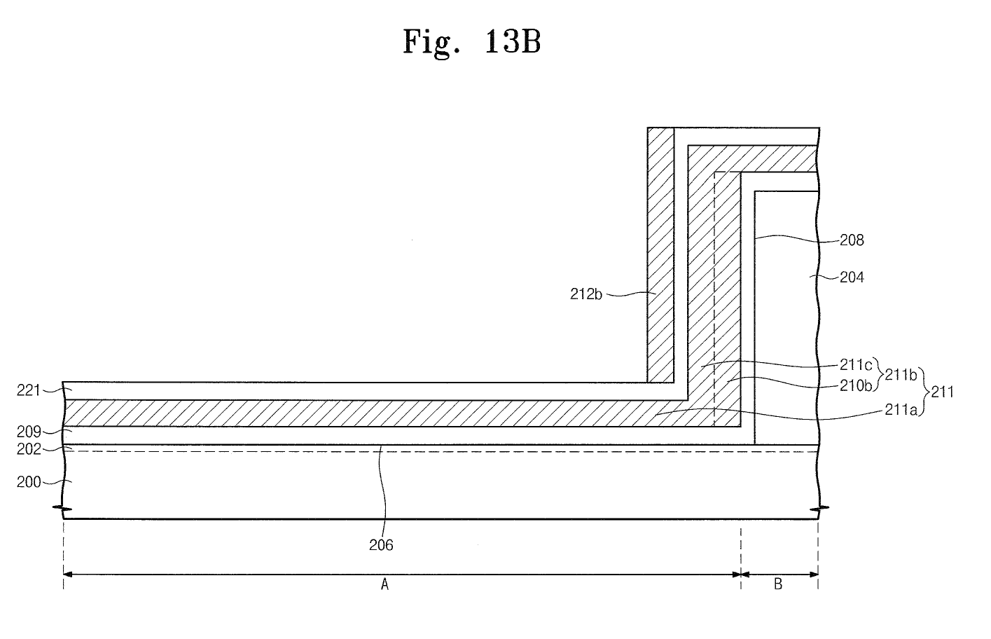

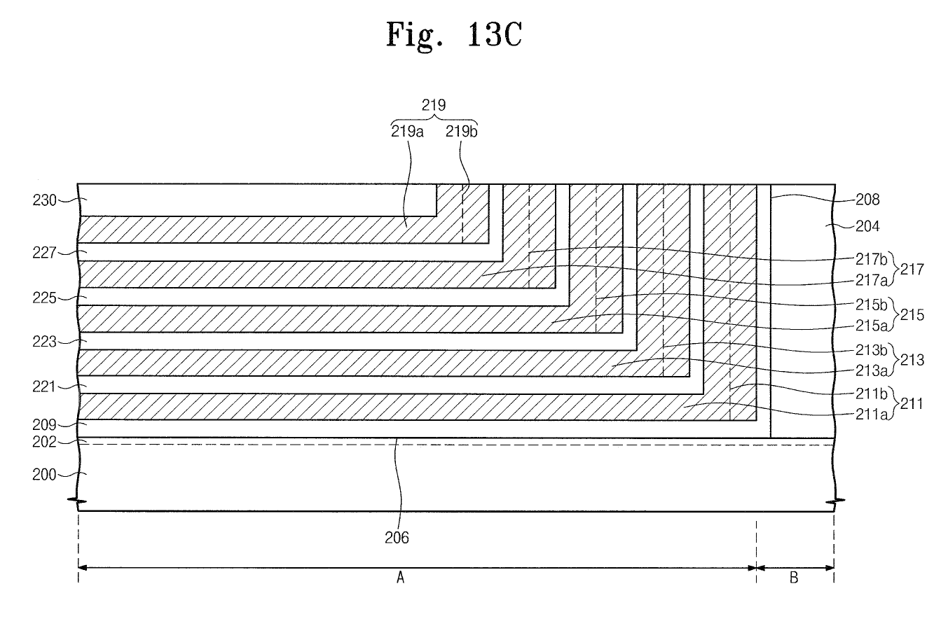

Hereinafter, a method for forming a semiconductor device according to an embodiment will be described with reference to FIGS. 13A through 13C.

FIGS. 13A through 13C are cross-sectional views illustrating a method for forming a semiconductor device according to an embodiment.

Referring to FIG. 13A, as described in FIG. 10A, a substrate 200 is provided. A ground select insulating layer 209 and an auxiliary ground select gate pattern 210 may be sequentially formed on a substrate 200. The auxiliary ground select gate pattern 210 may include an auxiliary ground select gate pattern flat portion 210a formed on the bottom surface 206 of a concave portion A of the substrate 200. The auxiliary ground select gate pattern 210 may include an auxiliary select gate pattern sidewall portion 210b extended over the side surface 208 of the concave portion A from the auxiliary ground gate pattern flat portion 210a. The auxiliary ground select gate pattern 210 may also be formed on the upper surface of a protruded portion B.

Referring to FIG. 13B, an etching process may be performed on the auxiliary ground select gate pattern 210 using the ground select insulating layer 209 as an etch stop layer. The etching process may be an anisotropic etching process. Due to the etching process, the auxiliary ground select gate pattern flat portion 210a may be removed, and the auxiliary ground select gate pattern sidewall portion 210b may be remained.

A ground select gate pattern 211 may be formed over the substrate 200. The ground select gate pattern 211 may include a ground gate pattern flat portion 211a over the bottom surface 206 of the concave portion A of the substrate 200. The ground select gate pattern 211 may include a ground select gate pattern sidewall portion 211b extended over the side surface 208 of the concave portion A from the ground select gate pattern flat portion 211a. The ground select gate pattern sidewall portion 211b may include a main ground select gate pattern sidewall portion 211c provided by the same process as performed on the ground select gate pattern flat portion 211a, and an auxiliary ground gate pattern sidewall portion 210b contacting the main ground select gate pattern sidewall portion 211c.

After the etching process, a first intergate insulating layer 221 may be formed over the substrate 200. A first auxiliary cell gate pattern may be formed over the first intergate insulating layer 221. A first auxiliary cell gate pattern sidewall portion 212b may be formed by performing an anisotropic etching the first auxiliary cell gate pattern using the first intergate insulating layer 221 as an etch stop layer.

Referring to FIG. 13C, gate patters 211, 213, 215, 217, and 219 may be formed to be spaced from each other by insulating layer 221, 223, 225, and 227 by the method described in connection with FIG. 13B. The gate patterns 211, 213, 215, 217, and 219 may include gate pattern flat portions 211a, 213a, 215a, 217a, and 219a, respectively, on the bottom surface of the concave portion A of the substrate 200. The gate patterns 211, 213, 215, 217, and 219 may include gate pattern sidewall portions 211b, 213b, 215b, 217b, and 219b, respectively, extended over the side surface 208 of the concave portion A from the gate pattern flat portions 211a, 213a, 215a, 217a, and 219a, respectively. Each of the gate pattern sidewall portions 211b, 213b, 215b, 217b, and 219b may include a main gate pattern sidewall portion provided by the same process as performed on the gate pattern flat portion 211a, 213a, 215a, 217a, and 219a, and an auxiliary gate pattern sidewall portion contacting the main gate pattern sidewall portion.

A string select insulating layer 230 may be formed on the string select gate pattern 219. A planarization process may be performed using the upper surface of the protruded portion 8 as an etch stop layer.

Thereafter, the method for forming a semiconductor device according to this embodiment may be provided by the method described in connection with FIGS. 9, 10D, and 10E.

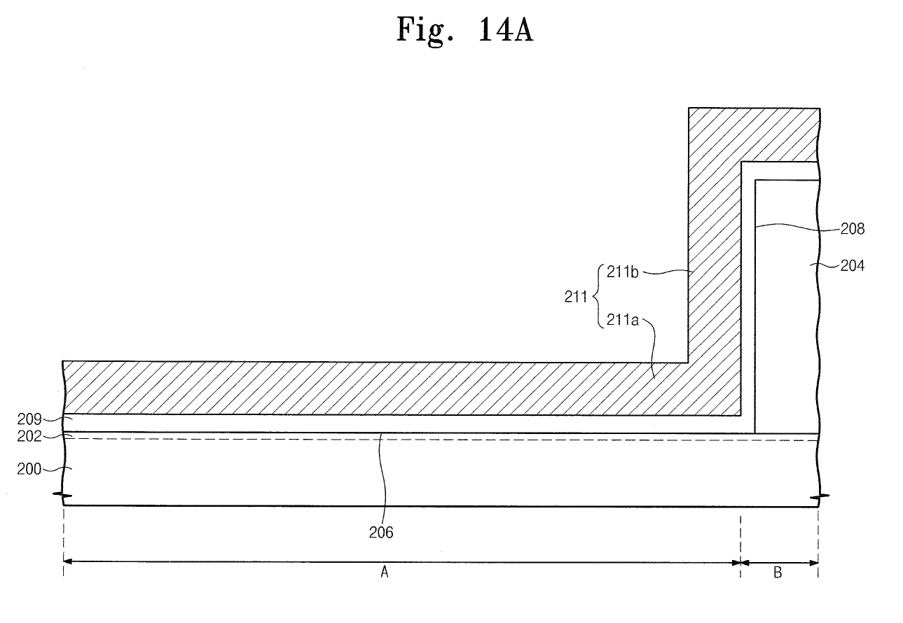

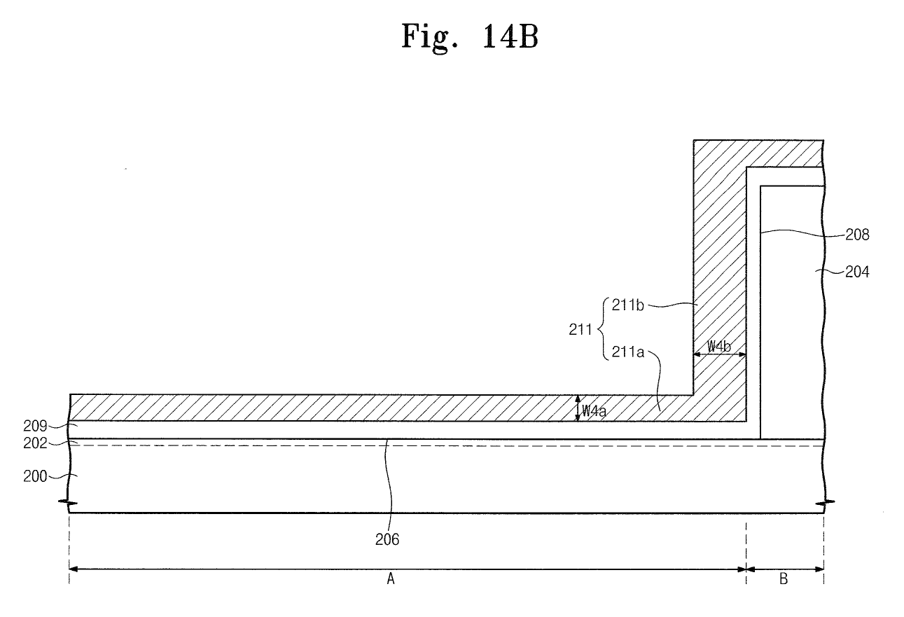

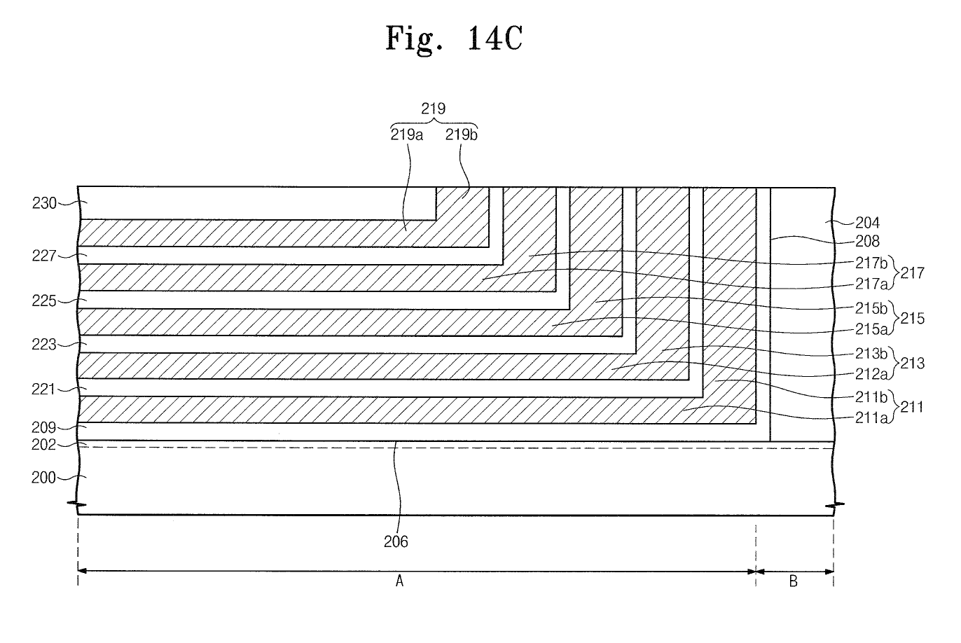

Hereinafter, a method for forming a semiconductor device according to an embodiment will be described in detail with reference to FIG. 14A through 14C.

FIGS. 14A through 14C are cross-sectional views illustrating a method for forming a semiconductor device according to an embodiment.

Referring to FIG. 14A, a ground select insulating layer 209 and a ground select gate pattern 211 may be sequentially formed over a substrate 200. The ground select gate pattern 211 may include a ground select gate pattern flat portion 211a over the bottom surface 206 of a concave portion A of the substrate 200. The ground select gate pattern 211 may include a ground gate pattern sidewall portion 211b extended over the side surface 208 of the concave portion A from the ground select gate pattern flat portion 211a.

Referring to FIG. 14B, an etching process may be performed on the ground select gate pattern 211. The etching process may be an anisotropic etching process. Due to the etching process, a portion of the ground select gate flat portion 211a may be removed. The ground select gate pattern flat portion 211a may have a thickness W4a smaller than a thickness W4b of the ground select gate pattern sidewall portion 221b.

Referring to FIG. 14C, gate patterns 211, 213, 215, 217, and 219 and insulating layers 221, 223, 225, and 227 may be alternately stacked over the substrate 200 by the method described in connection with FIG. 14B. The gate patterns 211, 213, 215, 217, and 219 may include gate pattern flat portions 211a, 213a, 215a, 217a, and 219a over the bottom surface 206 of the concave portion A of the substrate 200. The gate patterns 211, 213, 215, 217, and 219 may include gate pattern sidewall portions 211b, 213b, 215b, 217b, and 219b extended over the side surface 208 of the concave portion A from the gate pattern flat portions 211a, 213a, 215a, 217a, and 219a. The gate pattern sidewall portions 211b, 213b, 215b, 217b, and 219 may have a thickness greater than a thickness of the gate pattern flat portions 211a, 213a, 215a, 217a, and 219a. A string select insulating layer 230 may be formed on the string select gate pattern 219. A planarization process may be performed using the string select insulating layer 230 as an etch stop layer. Thereafter, the method according to this embodiment may be provided by the method described in connection with FIGS. 9, and 10D, and 10E.

Hereinafter, applications of a semiconductor device according to an embodiment will be described.

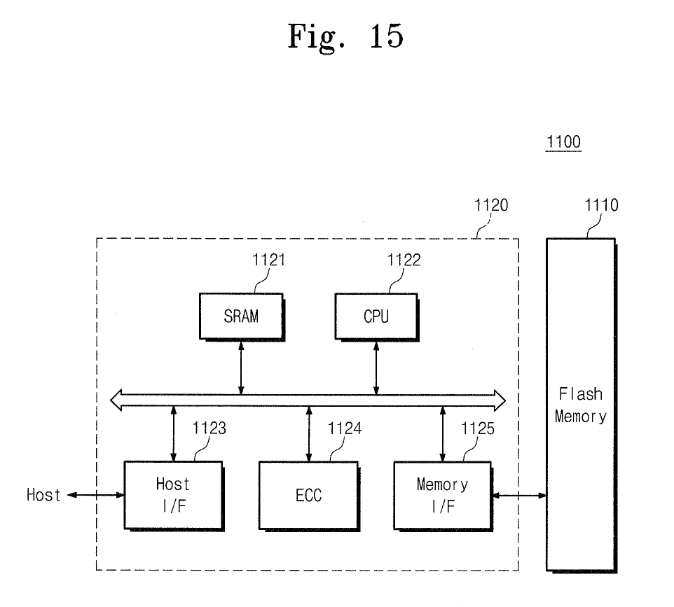

FIG. 15 is a block diagram illustrating an exemplary memory card 1100 including a semiconductor device according to an embodiment.

A semiconductor device according to an embodiment may be mounted in a memory card 1100 for supporting a large amount of data storage capacity. The memory card 1100 may include a memory controller 1120 controlling overall data exchanges between a host and the flash memory 1110.

The memory controller 1120 may include a processing unit 1122 controlling an operation of the memory card 1100, an SRAM 1121, an error correction block 1124, a host interface 1123, and a memory interface 1125. The SRAM 1121 may be used as an operation memory of the processing unit 1122. The host interface 1123 may include a data exchange protocol of the host connected to the memory card 1100. The error correction block 1124 may detect or correct an error included in data read out from the flash memory 1110. The memory interface 1125 may interface with the flash memory 1110. The processing unit 1122 may perform overall control operations for data exchanges of the memory controller 1120. The memory card 1100 can provide a system having high reliability due to improved reliability of the flash memory 1110 according to an embodiment.

Hereinafter, an application of a nonvolatile memory device according to the embodiments will be described.

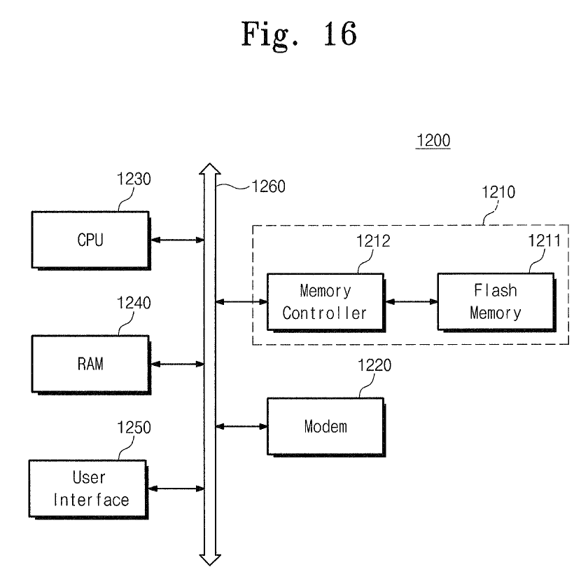

FIG. 16 is a block diagram illustrating a data processing system 1200 including a memory system 1210 having a semiconductor device according to an embodiment.

A semiconductor device according to an embodiment may include a memory system 1210. The memory system 1210 may be mounted in data processing systems, such as mobile devices and desktop computers. The data processing system 1200 may include a memory system 1210, a modem 1220 electrically connected to a system bus, a CPU 1230, a RAM 1240, and a user interface 1250. The memory system 1210 may store data processed by the CPU 1230 or external data. The memory system 1210 according to an embodiment may be implemented in a semiconductor disk device. According to an embodiment, the data processing system 1200 may stably store a large capacity data in the memory system 1210. Also, with the improved reliability of the semiconductor device, the memory system can reduce resources necessary for error correction, and provide a high rate data exchange function to the data processing system 1200.

A semiconductor device according to an embodiment may be mounted in various forms of packages. For example, the memory systems or storage devices may be mounted in packages, such as Package on Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), and Wafer-level Processed Stack Package (WSP).

According to an embodiment, a margin of a contact process can be increased by a plurality of material layers that have a sidewall, portion having a thickness greater than a thickness of a flat portion and are spaced from each other. The reliability of a semiconductor device can be enhanced.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1. A semiconductor device comprising:
a substrate comprising a concave portion having a bottom surface and a side surface, and a protruded portion extended from the side surface; and
a plurality of material layers having flat portions on the bottom surface and side portions extended over the side surface from the flat portions, and spaced from each other,
wherein at least one of the sidewall portions of the material layers has a thickness greater than a thickness of the flat portions of the material layers.

2. The semiconductor device of claim 1, further comprising gate patterns having gate pattern flat portions between the flat portions of the material layers and gate pattern sidewall portions between the sidewall portions of the material layers, wherein the material layers comprise a material having insulating properties.

3. The semiconductor device of claim 2, further comprising conductive patterns provided on upper surfaces of the gate pattern sidewall portions, wherein the conductive patterns have a width greater than a width of the gate pattern sidewall portions.

4. The semiconductor device of claim 1, further comprising gate insulating patterns between the material layers, wherein the material layers comprise a material having conductive properties.

5. The semiconductor device of claim 4, further comprising conductive patterns provided on upper surfaces of the sidewall portions of the material layers, wherein the conductive patterns have a width smaller than a width of the sidewall portions of the material layers.

6. The semiconductor device of claim 1, wherein the sidewall portions of the material layers have main sidewall portions provided by the same process as a process providing the flat portions, and auxiliary sidewall portions contacting the main sidewall portions.

7. The semiconductor device of claim 1, wherein the sidewall portions of the material layers have a width greater than an interval between two adjacent material layers of the material layers.

8. The semiconductor device of claim 1, wherein upper surfaces of the sidewall portions of the material layers are coplanar with an upper surface of the protruded portion, and the upper surface of the protruded portion is parallel to the bottom surface of the concave portion of the substrate.

9. The semiconductor device of claim 1, further comprising an active pillar upwardly extended from the bottom surface of the concave portion of the substrate and facing side surfaces of the flat portions of the material layers.

10. The semiconductor device of claim 1, further comprising an active pillar upwardly extended from the bottom surface of the concave portion of the substrate and passing through the flat portions of the material layers.

11-20. (canceled)
